(19) United States
(12) Patent Application Publication
(10) Pub. No.: US 2008/0231294 A1
(43) Pub. Date: Sep. 25, 2008

(54) STRUCTURAL HEALTH MONITORING CIRCUIT

(75) Inventors: Chao You, West Fargo, ND (US); Shirui Wang, Fargo, ND (US)

Correspondence Address: JOHN P. O'BANION;O'BANION & RITCHEY LLP, 400 CAPITOL MALL SUITE 1550, SACRAMENTO, CA, 95814, US

(73) Assignee: NDSU RESEARCH FOUNDATION, Fargo, ND (US)

(21) Appl. No.: 12/051,682

(22) Filed: Mar. 19, 2008

Related U.S. Application Data
(60) Provisional application No. 60/895,624, filed on Mar. 19, 2007.

(51) Int. Cl. G01R 17/00

(52) U.S. Cl. 324/725

(57) ABSTRACT

A structural health monitoring circuit apparatus and method are based on electrical impedance variations of a piezoelectric patch, which is attached to a structure to be monitored. The circuit compares a known good sweep of frequency-impedance pairs with a contemporaneous sweep to generate an alarm when an error bound is exceeded. The impedance of the piezoelectric patch is determined though adjustment of a variable reactance in a bridge configuration. By suitable design of the bridge elements, the electrical impedance of the piezoelectric patch may be directly measured. A microprocessor controlled version of this device consumes less than 2 W of power, which may be further reduced by further large scale integration or reduction to a state machine on a programmable gate array. Ultimately, this device may give personnel warnings to aircraft, automobiles, bridges, elevated roads, buildings, or home structural failures.

### CROSS-REFERENCE TO RELATED APPLICATIONS

This invention claims benefit of priority to U.S. Provisional patent application 60/895,624, filed Mar. 19, 2007, which is hereby incorporated by reference in its entirety.

### STATEMENT REGARDING FEDERALLY SPONSORED RESEARCH OR DEVELOPMENT

This invention was made with Government support under EPSCoR Grant No. EPS-0447679 awarded by the National Science Foundation (NSF). The Government has certain rights in this invention.

### INCORPORATION-BY-REFERENCE OF MATERIAL SUBMITTED ON A COMPACT DISC

Not Applicable

### BACKGROUND OF THE INVENTION

1. Field of the Invention

This invention pertains to structural health monitoring based on electrical impedance variations of a piezoelectric patch.

2. Description of Related Art

The development of systems and structures configured for monitoring their own structural integrity has become an active field. Traditional methods use Non-Destructive Evaluation (NDE) and Non-Destructive Testing (NDT), typically using very expensive equipment. However, in order to lower the inspection costs, the research on intelligent material systems is becoming an active field. This technology has practical applications in many areas such as bridges, homes, aerospace systems, machine parts, and civil buildings.

One example is a piezoelectric impedance-based structural health monitoring technique, which utilizes a piezoelectric patch attached to a structure and which measures electrical impedance of the piezoelectric patch within a certain frequency range. The frequency is maintained in the kHz range for optimum sensitivity in damage detection. Piezoelectric materials are used as both actuators and sensors.

The principle of piezoelectric impedance-based structural health monitoring is to measure the high frequency (e.g., 50 kHz to 400 kHz) impedance of the piezoelectric patch attached to a structure. Physical changes in the structure cause changes in the structural mechanical impedance. Due to electromechanical coupling between the piezoelectric patch and the structure, structural mechanical impedance variations indicate electrical impedance variations of the piezoelectric patch. Therefore, measuring electrical impedance can determine when structural damage has occurred.

A frequency range lower than 70 kHz covers a larger sensing area, while a frequency range higher than 200 kHz has been found to be more localized. At high frequencies, this technique is as sensitive as sophisticated traditional NDE techniques, because the wavelength of the excitation is small enough to detect minor changes in the structural integrity.

### BRIEF SUMMARY OF THE INVENTION

In one embodiment of the invention is an apparatus, comprising: a piezoelectric patch attached to a structure; means for measuring electrical impedance of the piezoelectric patch; and means for outputting the measured the electrical impedance of said piezoelectric patch at an input frequency to a computer readable medium.

Here, a variable reactance is an element in a first leg in the resonant bridge, and the piezoelectric patch is an element in a second leg in the resonant bridge. A clock generator drives a frequency input to the resonant bridge, where a first peak detector electrically is connected to the first leg of the resonant bridge and a second peak detector electrically connected to the second leg of the resonant bridge. A differential amplifier comprises inputs from the two peak detector outputs in order to detect when the bridge has achieved balance.

A window comparator has an input coupled to an output of the differential amplifier to detect bridge balance. The window comparator is output to a control circuit that independently controls the variable reactance and the clock generator.

In operation, the control circuit (which may be either a state machine or a microprocessor) controls the clock generator (typically a Voltage Controlled Oscillator) to generate a desired bridge input frequency. Then, the control circuit adjusts the variable reactance (typically a variable resistor, but may be a variable capacitor or a variable inductor) to achieve bridge balance. The settings of frequency and variable reactance may be recorded to a computer readable medium.

In one aspect of the invention, the variable reactance may comprise one or more elements selected from a group consisting of: a digitally controlled resistor, a digitally controlled capacitor, and a digitally controlled inductor.

In another aspect of the invention, a means for monitoring a state of health the structure may be provided. This means for monitoring may comprise: a comparison between an initial known good state of the structure; and a subsequent unknown state of the structure.

The known good state and the subsequent unknown state may be determined by a sweep of frequencies and their corresponding variable reactance set points needed to achieve balance of the resonant bridge.

In another aspect of the invention, an apparatus may comprise: a piezoelectric patch attached to a structure; a clock generator; a bridge circuit comprising an input coupled to an output of said clock generator, said bridge circuit configured to monitor variations in electrical impedance of said piezoelectric patch; a set of two peak detectors, each with an input coupled to an output of said bridge circuit; a differential amplifier with inputs coupled to an output of the two peak detectors; a comparator with an input coupled to an output of the differential amplifier; a control circuit with an input coupled to an output of said comparator, wherein: the control circuit controls an output frequency of the clock generator, and the control circuit control a variable reactance within the bridge circuit; and a data output to a computer readable medium, comprising a set point of the clock generator and a set point of the variable reactance within the bridge circuit.

Here, as above, the variable reactance may comprise a digital controlled component, such as a digital resistor or digital capacitor.

In another aspect of the invention, a structural heath monitoring apparatus may comprise: a clock generator; a bridge circuit having an input coupled to an output of said clock generator, said bridge circuit configured for monitoring variations in electrical impedance of said piezoelectric patch; a set of two peak detectors, each with an input coupled to an output of said bridge circuit; a differential amplifier with inputs coupled to an output of the two peak detectors; a comparator with an input coupled to an output of the differential amplifier; a control circuit with an input coupled to an output of said comparator, wherein: the control circuit controls an output frequency of the clock generator, and the control circuit control a variable reactance within the bridge circuit; wherein said apparatus is configured to electrically couple the piezoelectric patch to a structure and to monitor variations in electrical impedance in the piezoelectric patch that are indicative of structural heath of said structure; and a data output to a computer readable medium, comprising a set point of the clock generator and a set point of the variable reactance within the bridge circuit.

Here, the bridge circuit variable reactance may comprise a digital resistor or a digital capacitor.

In still another aspect of the invention, a method of structural health monitoring is disclosed, which comprises: providing a structural health monitoring circuit attached to a structure; providing an initial known good frequency sweep of the structural health monitoring circuit attached to the structure; subsequently sweeping the structural health monitoring circuit attached to the structure to generate a contemporaneous frequency sweep; and comparing the initial known good frequency sweep with the contemporaneous frequency sweep to generate a differential error.

Here, the differential error may be output to a computer readable medium for recording or subsequent data analysis. The comparing step may either be a digital comparing step or an analog comparing step.

The initial known good frequency sweep may comprise one or more frequencies. The initial known good frequency sweep may be performed in-situ after the structure has been completed, or alternatively performed prior to installation of the structure. In still another manner, the initial known good frequency sweep may be generated off-line through numerical modeling of the structure. For particular materials comprising the structure, the initial known good frequency sweep may span a frequency range from about 53 kHz to about 164 kHz.

In another aspect of the invention, an alarm may be generated when the differential error exceeds an error limit. The alarm may be transmitted to a computer readable medium, or alternatively be an audible and/or visual alarm for personnel that may be injured by damage to the structure.

Here, the error limit may be based on an average calculation or based on a root mean square (RMS) calculation.

In still another aspect of the invention, a computer readable medium may comprise a programming executable capable of performing on a computer the method described above.

In another aspect of the present invention, an electrical circuit that can be used instead of expensive analyzers to realize electrical impedance monitoring of a piezoelectric patch. In one beneficial embodiment, this circuit can generate a frequency sweep from 53 kHz to 164 kHz, and can measure and record electrical impedance over that frequency range. This frequency range allows for a large sensing area and impedance variations can be readily observed.

In one embodiment, an apparatus may comprise a piezoelectric patch configured for attachment to a structure, means electrically coupled to the piezoelectric patch for measuring electrical impedance of the piezoelectric patch, converting electrical impedance measurements to signals indicative of physical changes of said structure, and outputting said signals.

In one embodiment, the means may comprise a clock generator circuit, a bridge circuit having an input coupled to an output of the clock generator wherein the bridge circuit is configured for monitoring variations in electrical impedance of said piezoelectric patch, a peak detector circuit having an input coupled to an output of the bridge circuit, a differential amplifier circuit having an input coupled to an output of the peak detector circuit, a comparator circuit having an input coupled to an output of the differential amplifier circuit, and a control circuit having an input coupled to an output of the comparator circuit.

In one embodiment, the bridge circuit may be configured for measuring impedance of said piezoelectric patch explicitly, or for monitoring variations in electrical impedance of said piezoelectric patch.

Further aspects of the invention will be brought out in the following portions of the specification, wherein the detailed description is for the purpose of fully disclosing preferred embodiments of the invention without placing limitations thereon.

### BRIEF DESCRIPTION OF THE SEVERAL VIEWS OF THE DRAWING(S)

The invention will be more fully understood by reference to the following drawings FIGS. 1-34, which are for illustrative purposes only:

FIG. 1A is a side view model of an electromechanical interaction between a piezoelectric patch and a structure.

FIG. 1B is a one dimensional model of an electromechanical interaction between a piezoelectric patch and a structure.

FIG. 2 is a diagram of a basic bridge circuit.

FIG. 3 is a simplified block diagram of an embodiment of an impedance-based structural health monitoring circuit according to the present invention.

FIG. 4 is a block diagram of an embodiment of the clock generator shown in FIG. 3.

FIG. 5 is a schematic diagram of an embodiment of the counter in the clock generator shown in FIG. 4.

FIG. 6 is a schematic of an embodiment of the D/A converter shown in FIG. 4.

FIG. 7 is a schematic of an embodiment of the operational amplifier shown in FIG. 4.

FIG. 8 is a schematic of an embodiment of the DC-DC converter shown in FIG. 4.

FIG. 9 is a schematic of the pin connections of the MC14046B used in the VCO shown in FIG. 8.

FIG. 10 is a schematic of an embodiment of a bridge circuit using the digital resistor of FIG. 3.

FIG. 11 is a graph of the digital resistor resistance per step.

FIG. 12A is a block diagram of a DS1666 digital resistor.

FIG. 12B is a schematic of the pin connection of the DS1666 digital resistor depicted in FIG. 12A.

FIG. 13 is a schematic of an embodiment of the peak detector shown in FIG. 3.

FIG. 14 is a graph showing simulation results for the peak detector shown in FIG. 13.

FIG. 15 is a schematic of an embodiment of the differential operational amplifier shown in FIG. 3.

FIG. 16 is a schematic of an embodiment of the compare circuit shown in FIG. 3.

FIG. 17 is a state flow diagram of the resonant bridge circuit adjustment control loop.

FIG. 18 is a detailed block diagram of an embodiment of the control circuit shown in FIG. 3.

FIG. 19 is a schematic of an embodiment of the clock shown in FIG. 18.

FIG. 20 is a schematic of an embodiment of the control circuit shown in FIG. 3.

FIG. 21 is a detailed block diagram of an embodiment of an impedance-based structural health monitoring circuit according to one embodiment of the invention.

FIG. 22A is a block diagram of an experimental setup for testing.

FIG. 22B is a block diagram of the health-based impedance monitoring circuit data being output to one or more computer readable media.

FIG. 23 is a diagram of an aluminum plate and piezoelectric patch, where the aluminum plate is tested with and without damage (simulated by a hole).

FIG. 24A is a graph showing undamaged aluminum plate impedance-frequency curves.

FIG. 24B is a graph showing damaged aluminum plate impedance-frequency curves.

FIG. 25A is an average value curve of undamaged aluminum plate impedance-frequency curves.

FIG. 25B is an average value curve of damaged aluminum plate impedance-frequency curves.

FIG. 25C is a comparison of average values of the undamaged and damaged aluminum plate impedance-frequency curves.

FIG. 26A is an undamaged aluminum plate impedance-frequency curve plotted by an impedance analyzer.

FIG. 26B is a damaged aluminum plate impedance-frequency curve plotted by an impedance analyzer.

FIG. 27 is a diagram showing a piezoelectric sensing area in an aluminum plate.

FIG. 28 is a graph showing the impedance-frequency curves of the average values of undamaged and 9 holes damaged aluminum plates.

FIG. 29 is a diagram of a wood plate and piezoelectric patch.

FIG. 30A is a graph of an undamaged wood plate impedance-frequency curve.

FIG. 30B is a graph of a damaged wood plate impedance-frequency curve.

FIG. 31A is a graph of an average value of undamaged wood plate impedance-frequency curve.

FIG. 31B is a graph of an average value of damaged wood plate impedance-frequency curve.

FIG. 31C is a graph of the average values of the undamaged and damaged wood plate impedance-frequency curves.

FIG. 32A is a graph of the undamaged wood plate impedance-frequency curve plotted by an impedance analyzer.

FIG. 32B is a graph of the damaged wood plate impedance-frequency curve plotted by an impedance analyzer.

FIG. 33 is a diagram of a piezoelectric sensing area in a wood plate.

FIG. 34 is a graph of the impedance-frequency curves of the average values of undamaged and 9 holes damaged wood plate.

### DETAILED DESCRIPTION OF THE INVENTION

### Definitions

“Mechanical impedance” means Mechanical impedance is typically known as the force-displacement curve of a structure, which is usually very frequency dependent. Mechanical impedance is a measure of how much a structure resists motion when subjected to a given force. It relates forces with velocities acting on a mechanical system. The mechanical impedance of a point on a structure is the ratio of the force applied to the point to the resulting velocity at that point.

Mechanical impedance is the inverse of mechanical admittance or mobility. The mechanical impedance is a function of the frequency w of the applied force and can vary greatly over frequency. At resonance frequencies, the mechanical impedance will be lower, meaning less force is needed to cause a structure to move at a given velocity.

The equation describing mechanical impedance is f (ω)=Z(ω)v(ω) where, f(ω) is the force vector, v(ω) is the velocity vector, Z(ω) is the impedance matrix, and ω is the frequency.

“j” is the square root of −1.

“Computer” means any device capable of performing the steps, methods, or producing signals as described herein, including but not limited to: a microprocessor, a microcontroller, a video processor, a digital state machine, a field programmable gate array (FGPA), a digital signal processor, a collocated integrated memory system with microprocessor and analog or digital output device, a distributed memory system with microprocessor and analog or digital output device connected by digital or analog signal protocols.

“Computer readable medium” means any source of organized information that may be processed by a computer to perform the steps described herein to result in, store, perform logical operations upon, or transmit, a flow or a signal flow, including but not limited to: random access memory (RAM), read only memory (ROM), a magnetically readable storage system; optically readable storage media such as punch cards or printed matter readable by direct methods or methods of optical character recognition; other optical storage media such as a compact disc (CD), a digital versatile disc (DVD), a rewritable CD and/or DVD; electrically readable media such as programmable read only memories (PROMs), electrically erasable programmable read only memories (EEPROMs), field programmable gate arrays (FGPAs), flash random access memory (flash RAM); and information transmitted by electromagnetic or optical methods including, but not limited to, wireless transmission, copper wires, and optical fibers.

Introduction

Many non-destructive evaluation (NDE) techniques monitor variations in mechanical impedance within a structure. Changes in the mechanical impedance of a structure may be caused by damage within the structure.

Piezoelectric materials may be used to couple mechanical and electrical impedances. A piezoelectric patch, attached to a test structure, may be electronically excited, thereby causing stress generated waves to be transmitted within the structure. As the structure-borne waves are influenced by the presence of damage within the structure, so will be the electrical response of the piezoelectric patch. By analyzing the electrical response of the piezoelectric patch in the frequency domain, impedance variations in the piezoelectric patch may be used to determine structural damages.

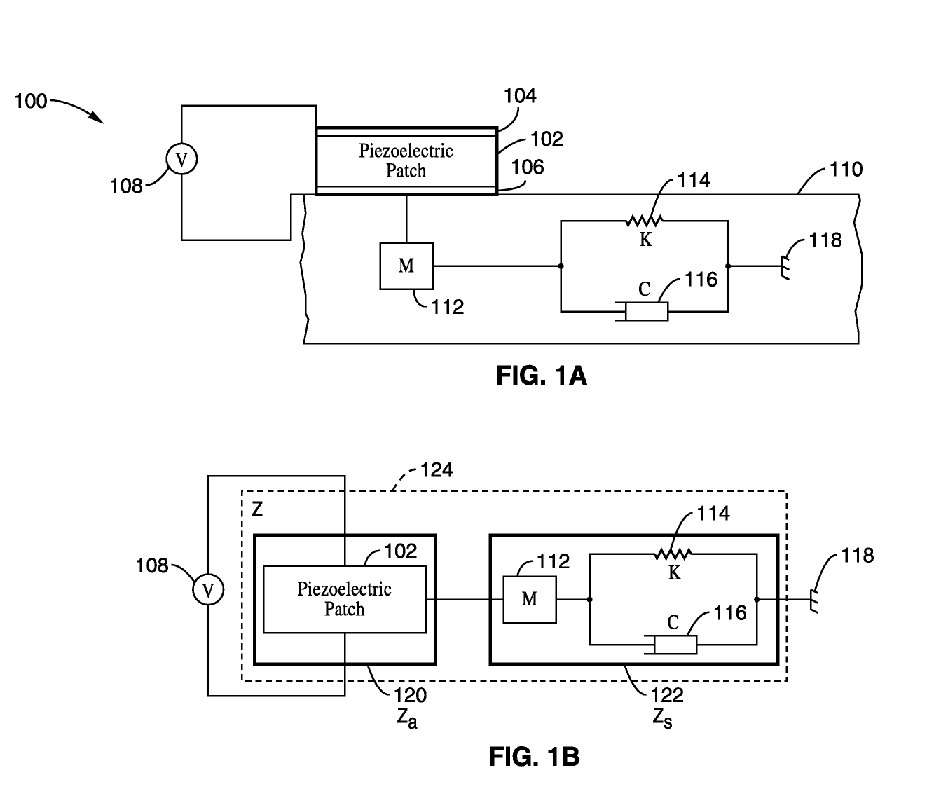

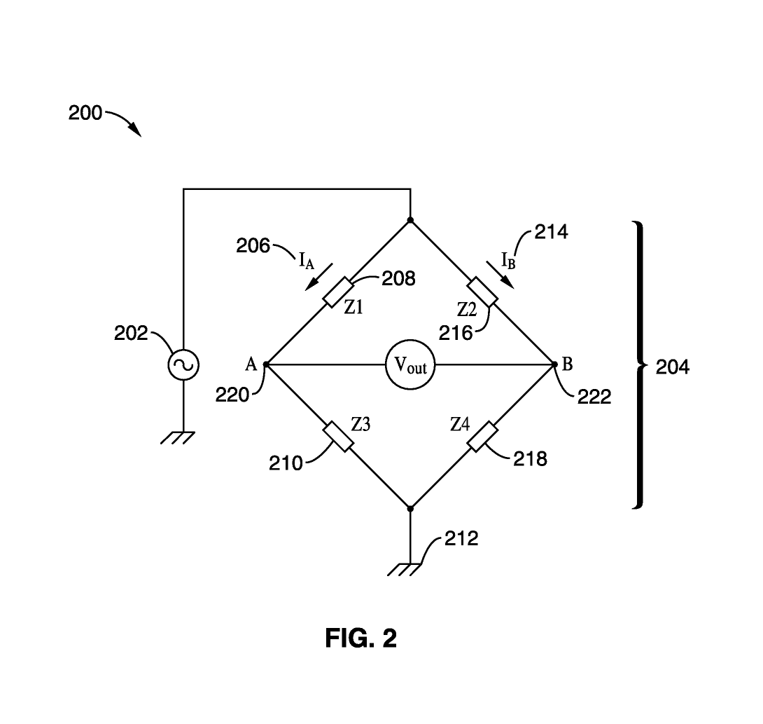

Refer now to FIG. 1A, which is a partial side view of a piezoelectric patch coupled to an arbitrary structure 100. Here, a piezoelectric patch 102, which may or may not have upper electrode 104 and lower electrode 106, is driven by a voltage source 108, which is generally alternative current (AC) in nature. The lower electrode 106 (or the bulk of the piezoelectric patch 102) is bonded to an arbitrary structure 110. A very simple arbitrary structure may ordinarily be modeled by a collection of one or more masses 112 attached to springs 114, and dampers 116, which are in turn connected to a ground 118.

Refer now to FIG. 1B, which shows the impedances of the various components coupling together. Here, the piezoelectric patch 102 is modeled with source impedance Zₐ 120 when driven by voltage source 108. The piezoelectric patch 102 is coupled to the arbitrary structure, which has a structural impedance of Zₛ 122. The coupled impedance Z 124 results from physically interconnecting the piezoelectric patch source impedance Zₐ 120 with the structural impedance of Zₛ 122.

In reality, it is understood that the arbitrary structure is not a simple mass, spring, and damper system as shown in FIGS. 1A and 1B. Rather, the arbitrary structure may have a generalized impedance that is a function of frequency, with the possibility of multiple resonances and “dead” frequencies at particular spatial locations on the surface of the arbitrary structure.

The interaction between a piezoelectric patch and a structure can be considered as a one-dimensional model as FIG. 1B. The mechanical aspect of the piezoelectric patch is described by its short-circuit mechanical impedance Zₐ 120. The host structure is described by its driving point mechanical impedance Zₐ 122, which includes the effect of mass stiffness, damping, and any surface interconnection boundary conditions. The piezoelectric patch is powered by voltage source 108 V=v sin(ωt) or I=i sin(ωt+φ). The entire electro-mechanical system is electrically represented by electrical impedance that is affected by the dynamics of the piezoelectric patch and the host structure.

The frequency dependent electrical admittance as seen by the voltage source 108 is:

$$\begin{matrix}Y ( ω ) = \frac{1}{Z ( ω )} \\ = jω \frac{{w}_{a} {l}_{a}}{{h}_{a}} ( {ɛ}_{33}^{T} ( 1 - jδ ) - \frac{{Z}_{s} ( ω )}{{Z}_{s} ( ω ) + {Z}_{a} ( ω )} {( {d}_{3 x} )}^{2} {Y}_{xx}^{E} )\end{matrix} \qquad ( 1 )$$

where Y is the electrical admittance (the inverse value of electrical impedance), Zₐ is the mechanical impedance 120 of the piezoelectric patch 102, Zₛ is the mechanical impedance 122 of the structure, Yₓₓ^{E} is Young's modulus of the piezoelectric patch at zero electric field, d₃ₓ is the piezoelectric strain constant at zero stress, ∈₃₃^{T} is the permittivity at zero stress, δ is the dielectric loss tangent of the piezoelectric patch, wₐ is the width of the piezoelectric patch, lₐ is the length of the piezoelectric patch, and ha is the thickness of the piezoelectric patch.

The first term,

$$jω \frac{{w}_{a} {l}_{a}}{{h}_{a}}$$

in Eq. 1 is the capacitive admittance of a free piezoelectric patch which increases in an electrical admittance with frequency. The second term of Eq. 1 is

$${ɛ}_{33}^{T} ( 1 - jδ ) - \frac{{Z}_{s} ( ω )}{{Z}_{s} ( ω ) + {Z}_{a} ( ω )} {( {d}_{3 x} )}^{2} {Y}_{xx}^{E} ,$$

the mechanical impedance of the piezoelectric patch 120 and structure 122. When a piezoelectric patch 102 is attached to a structure 110, piezoelectric patch mechanical impedance Zₐ 120 is fixed. Structure impedance Zₛ 122 determines the overall admittance Z 124. The contribution of the second term shows in the admittance versus frequency plot as resonant peaks when Zₛ(ω)+Zₐ(ω) approaches zero and resonance occurs. Since these resonant peaks correspond to specific structural resonances, they constitute a description of the dynamic behavior of the structure [3].

Equation 1 may be rearranged so as to solve for Zₛ(ω) as

$${Z}_{s} ( ω ) = {Z}_{a} ( ω ) ( \frac{{ɛ}_{33}^{T} ( 1 - jδ ) - \frac{Y ( ω ) {h}_{a}}{jω {w}_{a} {l}_{a}}}{{( {d}_{3 x} )}^{2} {Y}_{xx}^{E} - {ɛ}_{33}^{T} ( 1 - jδ ) + \frac{Y ( ω )}{jω {w}_{a} {l}_{a}}} ) \qquad ( 2 )$$

Eq. 2 shows that the mechanical impedance of a structure is determined by the electrical admittance of a piezoelectric patch attached to the structure. In other words, structural integrity can be investigated by monitoring electrical impedance. In addition, the real part of electrical impedance is more reactive to changes in structural integrity than the imaginary part.

In Eq. 1, ∈₃₃^{T} is temperature sensitive. As shown in Eq. 3,

∈₃₃^{T}=∈₀K (3)

where the permittivity is proportional to the relative dielectric constant, K, which is temperature sensitive and plays the most significant effect on the electrical impedance of the piezoelectric patch. ∈₀ is the permittivity of free space. The piezoelectric strain constant d₃ₛ and the Young's modulus Yₓₓ^{E} depend on the change in temperature. An increase in temperature leads to the shifting of resonant frequencies and fluctuations in resonant spike magnitudes. The shifting of resonant frequencies indicates a variation in the structural stiffness, caused by changes in the material and structural dimensional properties. The fluctuations in spike magnitudes indicate a damping related phenomenon. Therefore, both a combination of both structural stiffness and damping variations result from the temperature change.

Bridge Circuit

An embodiment of the invention uses an electronic bridge circuit. The bridge circuit is used either for measuring impedance explicitly, or for monitoring variations in electrical impedance. A bridge circuit is a geometric configuration of four known and unknown impedances. Elements may be a combination of resistors, inductors, and capacitors.

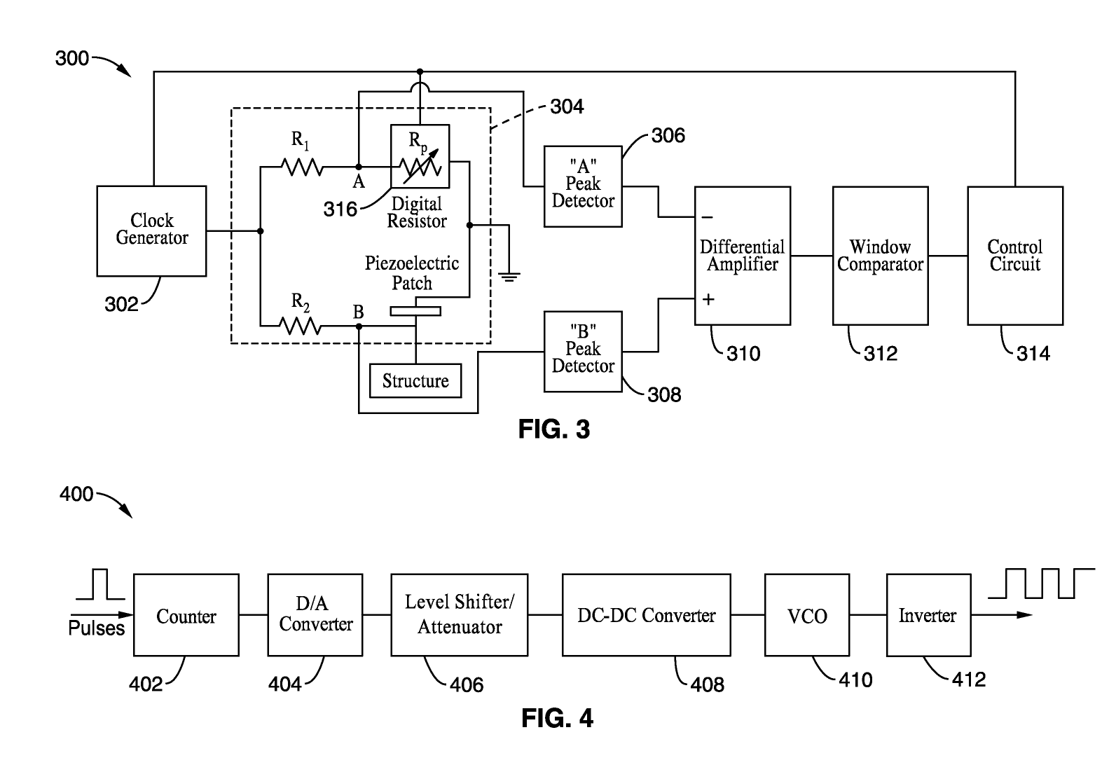

Refer now to FIG. 2, which depicts a Wheatstone 200. The bridge circuit is driven by an AC voltage source 202, as shown in FIG. 2. The Wheatstone bridge 204 is comprised of one leg with current I_{A} 206, a first impedance element Z₁ 208, a second impedance element Z₃ 210, which then flows to ground 212. The second leg of the Wheatstone bridge is a second current leg I_{B} 214 that comprises a first impedance element Z₂ 216, and a second impedance element Z₄ 218.

On the first leg of the Wheatstone bridge, test point A 220 is found between the first impedance element Z₁ 208 and the second impedance element Z₃ 210. Similarly, on the second current leg, test point B 222 is found between first impedance element Z₂ 216, and the second impedance element Z₄ 218. The voltage between test point A and test point B is defined as Vₒᵤₜ 224.

When the voltage between point A 220 and B 222 is zero, the bridge circuit is said to be balanced, or V_{A}−V_{B}=0. The voltage at test point A is V_{A}=Vₚ cos(ωt+φₚ) and the voltage at B is V_{B}=V_{q} cos(ωt+φ_{q}). For both points A and B to be equal, that is V_{A}=V_{B}, requires Vₚ=V_{q} and φₚ=φ_{q}. Thus, I_{A}Z₃=I_{B}Z₄, I_{A}(Z₁+Z₃)=I_{B}(Z₂+Z₄), and is

$$\frac{{Z}_{1}}{{Z}_{3}} = \frac{{Z}_{2}}{{Z}_{4}} \qquad ( 4 )$$

for the well known reactive Wheatstone bridge balance equation.

Impedance-Based Structural Health Monitoring Circuit Design

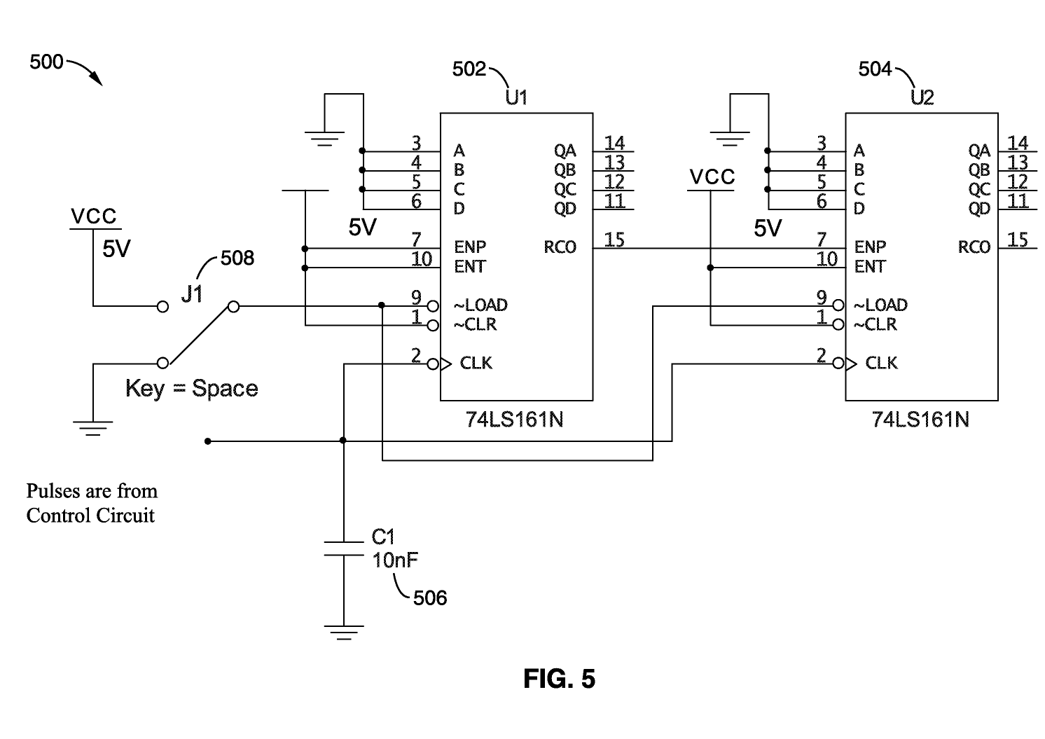

Refer now to FIG. 3, which is in exemplary embodiment of an impedance-based structural health monitoring circuit 300 according to the invention. In FIG. 3, the impedance-based structural health monitoring circuit 300 comprises a clock generator 302, a bridge circuit 304, a peak detector circuit for test point A 306, a peak detector circuit for test point B 308, a differential amplifier circuit 310, a window comparator circuit 312, and a control circuit 314. This is a simplified block diagram of the circuit operation.

The clock generator 302 generates a frequency sweep from 53 kHz to 164 kHz square wave, which is used by the bridge circuit 304. The peak detectors 306 and 308 are connected at their respective outputs of the bridge circuit 304 to detect the voltage amplitudes of test points A and B. The differential amplifier 310 is used to compare these two amplitudes from peak detectors 306 and 308. The window comparator circuit 312 determines whether the bridge circuit 304 is balanced and generates a digital signal (“0” not balanced, and “1” balanced). If the bridge circuit 304 is not balanced, the resistance of the digital resistor 316 will be continually increased, and the clock generator 302 will maintain the same clock frequency. If the bridge circuit 304 is balanced, the control circuit 314 will hold and record the values of the digital resistor 316 and the clock generator 302. After a certain time, the control circuit 314 will generate a signal to reset the digital resistor 316 and increase the frequency of the clock generator 302 to complete the next measurement process.

Now that the basic building blocks of the impedance-based structural health monitoring circuit 300 are understood, each major component will well be described in more detail.

Clock Generator

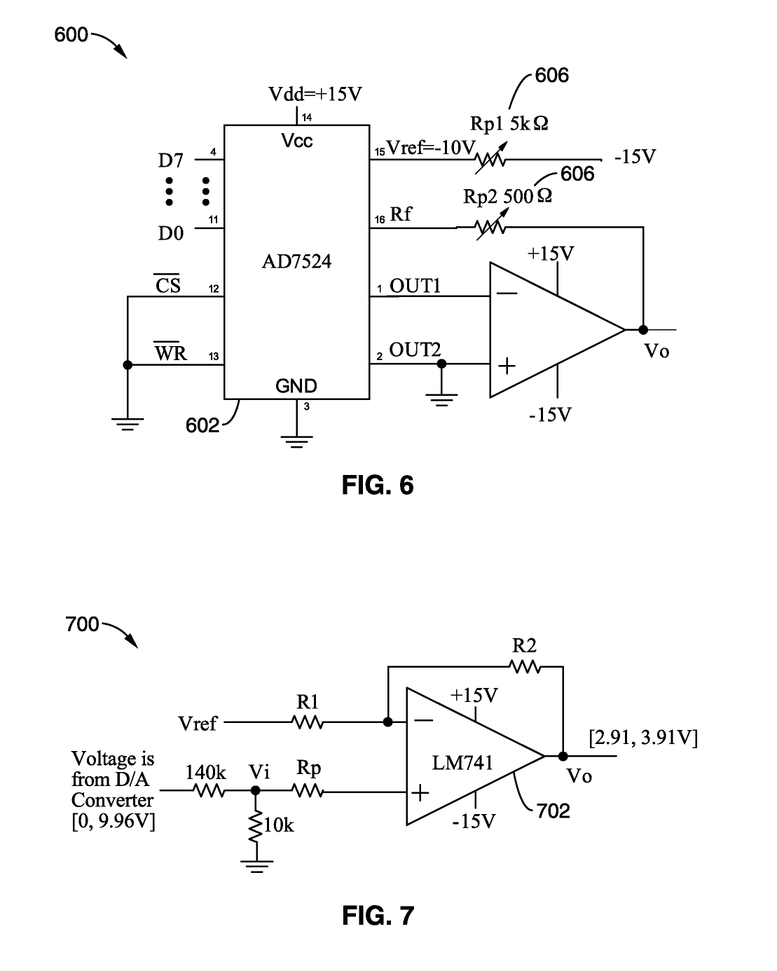

Refer now to FIG. 4, which shown one embodiment of a clock generator 400. The clock generator 400 is used to generate a swept frequency signal, and comprises six major functional blocks of circuits: a counter 402, a digital to analog converter (D/A converter) 404, a level shifter/attenuator 406, a DC-DC converter 408, a voltage controlled oscillator (VCO) 410, and an inverter 412.

The frequency sweep is realized by tuning the input voltage of a VCO 410. The counter 402 and D/A converter 404 combination provides a digitally controlled output voltage. Because the VCO 410 has an input voltage range that generates the frequency sweep from 53 kHz to 164 kHz, a level shifter/attenuator 406 and a DC-DC converter 408 are used to transform the output voltage of D/A converter 404 correspond to the input voltage range of the VCO 410. The frequency sweep is digitally controlled by the clock pulses to the counter 402. These clock pulses are derived from the control circuit (discussed below) controlling the counter 402. In other words, the control circuit determines when the clock generator will change the generator output frequency.

1. Counter in Clock Generator

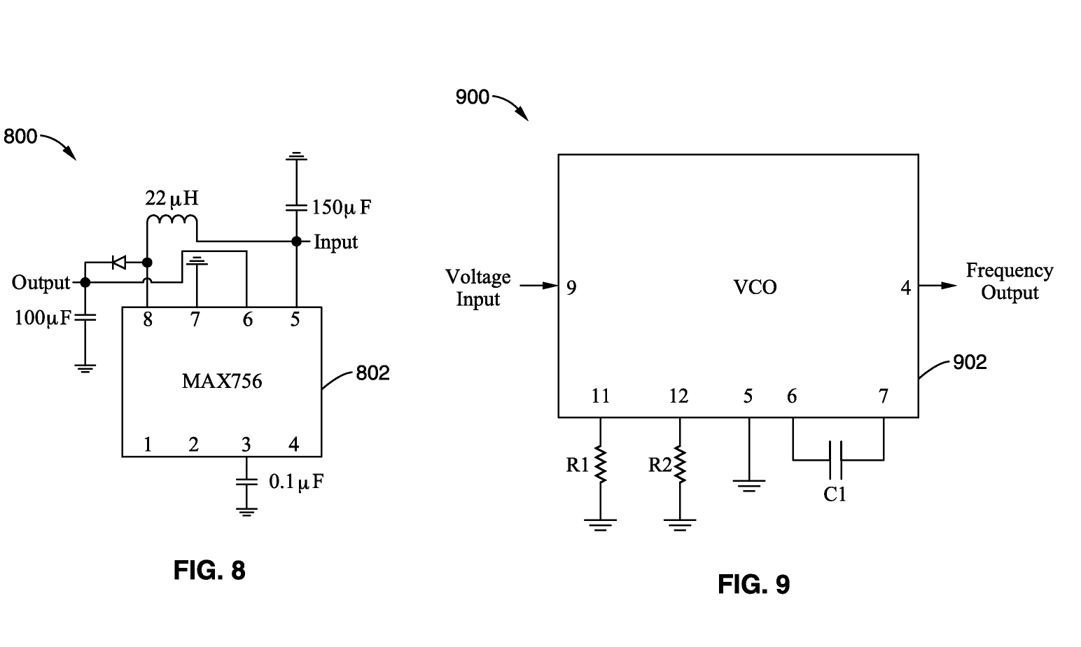

Refer now to the schematic shown in FIG. 5. In one embodiment, a counter 500 is used to control the digital input of a D/A converter. Two 4-bit binary synchronous counters (74LS161) 502 and 504 may be used to realize the digital count from “00000000” to “111111111”. Capacitor (C₁) 506 may be added for stability. The clock of counter (pulses) originates from the control circuit which will be presented later, and are showing here as a mere switch 508.

2. D/A converter

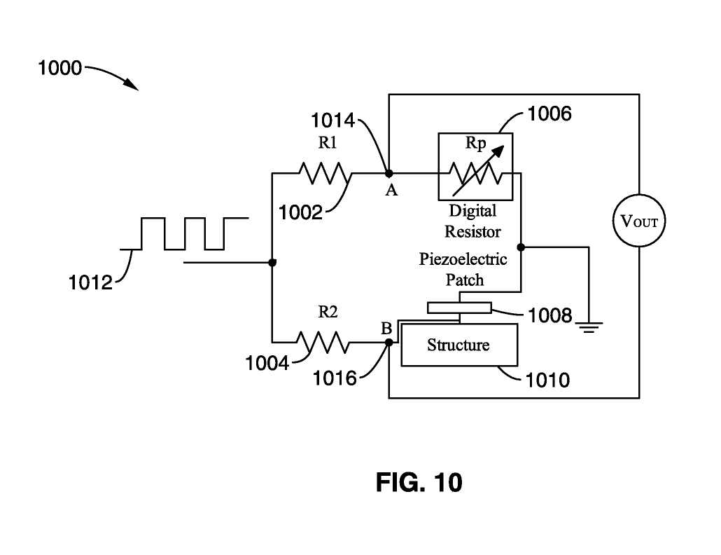

Refer now to the schematic shown in FIG. 6. An 8-bit D/A converter 600 is realized by using one AD7524 602 and LM741 604. Resistors Rp1 606 and Rp2 608 are used for enhanced accuracy.

This D/A converter 602 can provide 256 different output voltages, which may be used as inputs by the VCO 410 of FIG. 4 to generate clocks of 256 different frequencies. When the input of D0-D7 is “111111111”, the output voltage should be

$${V}_{o max} = - \frac{{V}_{ref}}{{2}^{n}} ( {2}^{n} - 1 ) = \frac{10}{256} ( 255 ) = 9.96 V \qquad ( 5 )$$

3. Level Shifter/Attenuator

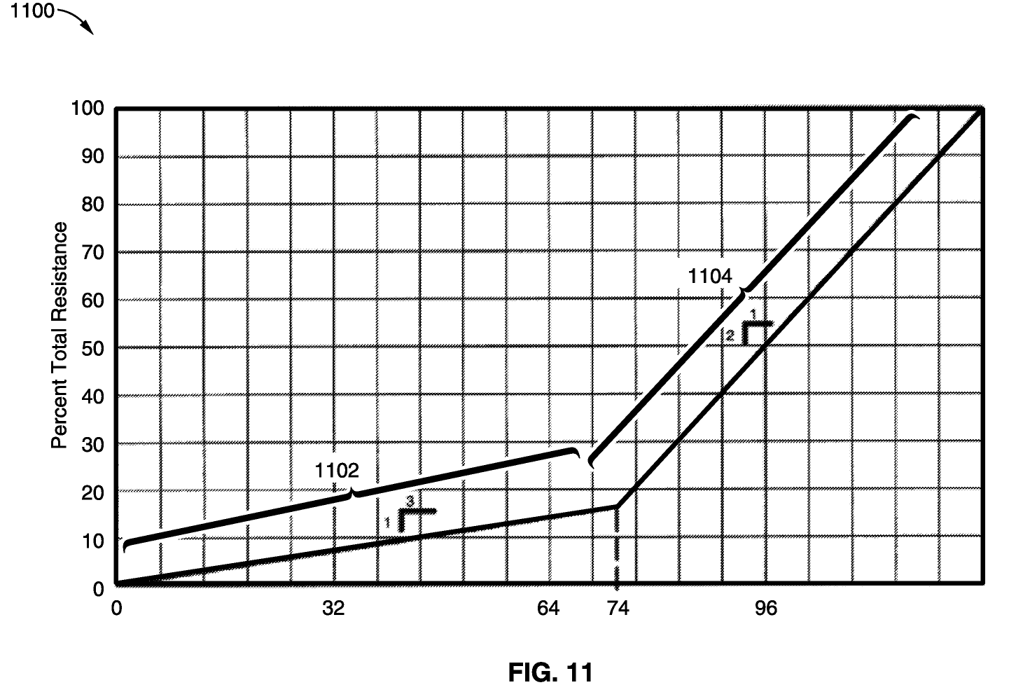

Refer now to FIG. 7, which is a schematic 700 of a level shifting and scaling operational amplifier 702. The output voltage of the D/A converter ranges from 0 V to 9.96 V. However, the VCO requires that the input voltage range from 2.91 V to 3.91 V to generate the frequency from 53 kHz to 164 kHz. Thus, a level shifter/attenuator is essential to change the voltage range from 0 V −9.96 V to 2.91 V −3.91 V. To make the output voltage of the D/A converter match the input needs of the level shifter/attenuator, a voltage divider which consists of 140 kΩ and 10 kΩ resistors is used, as shown in FIG. 7 pocket. The equation is given by

$${V}_{o} = \frac{{R}_{1} + {R}_{2}}{{R}_{1}} {V}_{i} - \frac{{R}_{2}}{{R}_{1}} {V}_{ref} . \qquad ( 6 )$$

where R₁=1 kΩ, R₂=506Ω, Rₚ=R₁//R₂=336Ω (Rₚ is for accuracy) and V_{ref}=−5.75 V. After the level shifter attenuator, Vₒ is in voltage range of 2.91 V to 3.91 V.

4. DC-DC Converter

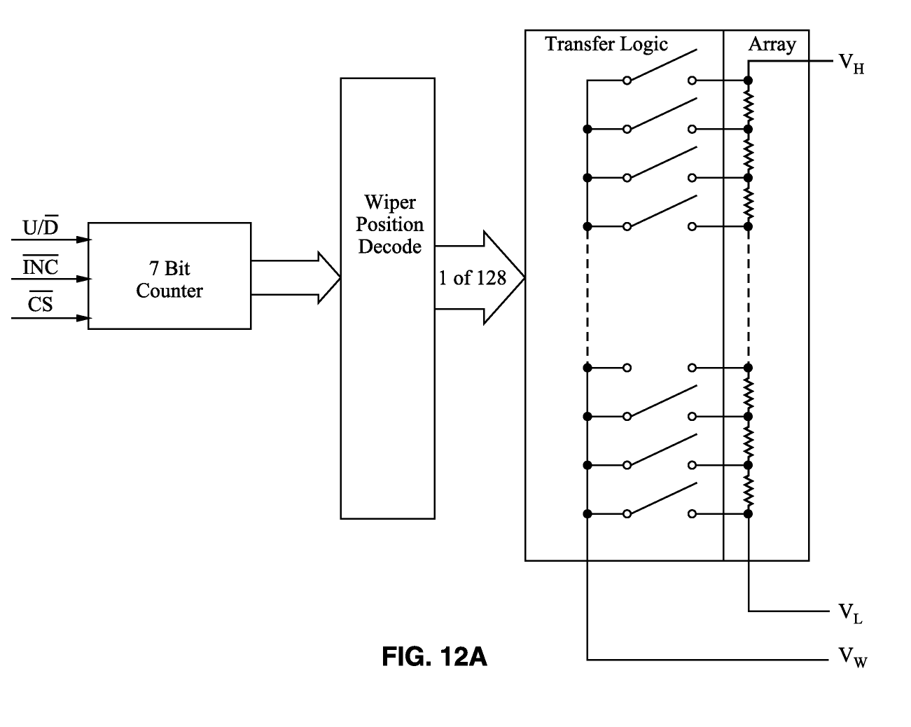

Refer now to FIG. 8, which shows the schematic 800 and pin out of the DC-DC converter 802. The voltage fluctuates at the output of the level shifter/attenuator previously discussed in FIG. 7. The fluctuation has to be removed because it can cause the output frequency of the VCO to fluctuate. Therefore, a DC-DC converter is placed at the output of the level shifter/attenuator to reduce the fluctuation.

5. Voltage Controlled Oscillator (VCO)

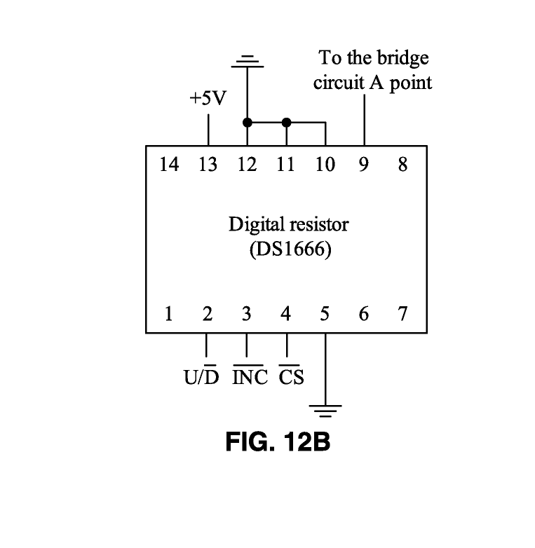

Refer now to FIG. 9, which shows the schematic 900 of the VCO 902. The VCO 902 is perhaps the most important part of the clock generator. A voltage input range from 2.91 V −3.91 V generates an output clock frequency of 53 kHz −164 kHz. This frequency range involves 256 different steps. The MC14046B Phase Locked Loop that contains a VCO can satisfy this frequency requirement. The pin connection is shown in FIG. 9.

Minimum and maximum output frequencies are determined by

$$\begin{matrix}{f}_{min} = \frac{1}{{R}_{2} ( {C}_{1} + 32 pF )} & ( 7 ) \\ {f}_{max} = \frac{1}{{R}_{1} ( {C}_{1} + 32 pF )} + {f}_{min} \\ where \\ 10 K \leq {R}_{1} \leq 1 M \\ 10 K \leq {R}_{2} \leq 1 M \\ 100 pF \leq {C}_{1} \leq 0.01 µF . & ( 8 )\end{matrix}$$

These two equations are only used as design guide. In this design, R1=2.5 kΩ, R2=1 MΩ and C1=0.01 μF.

6. Inverter

Refer back to FIGS. 3 and 4 once again. The reason an inverter 412 (DM7404) is disposed between the clock generator 410 and the bridge circuit 304 is that piezoelectric patch disposed within the bridge circuit 304 may deform the wave shape of the clock signal from the VCO 410. The inverter 412 is therefore used as a buffer to rectify voltage high and voltage low of the clock signal so as to keep the clock signal at the same frequency as was intended as the output of the VCO 410.

Bridge Circuit

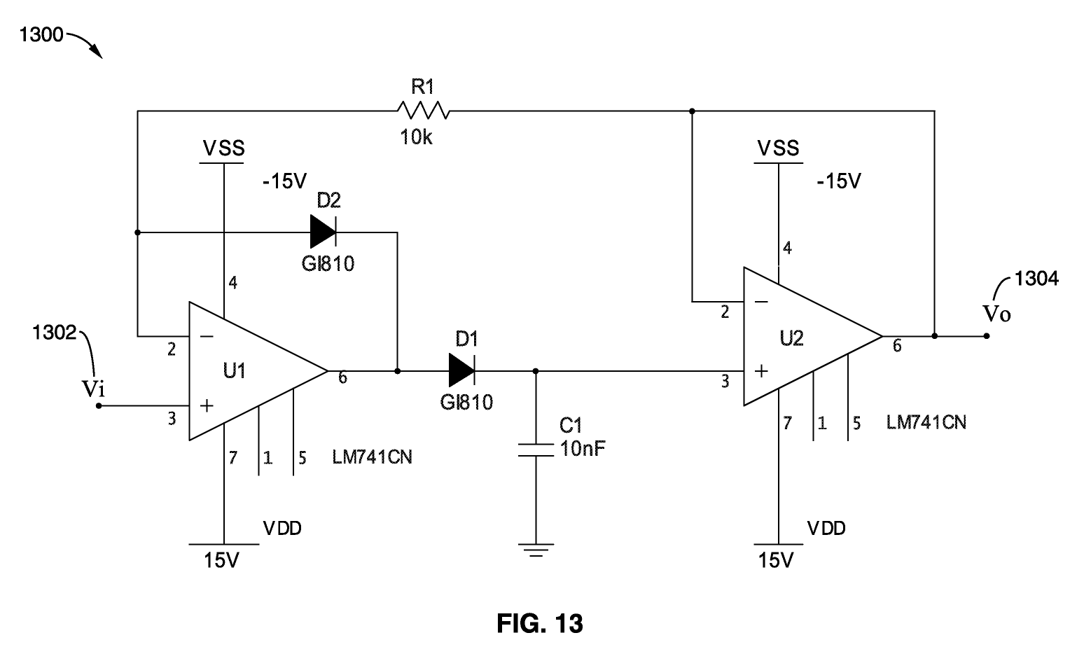

Refer now to FIG. 10, which is a schematic 1000 of one configuration of an exemplary bridge circuit used in the impedance-based structural health monitoring circuit previously shown in FIG. 3. This circuit comprises two resistors R1 1002 and R2 1004, one digital resistor (DS1666) 1006, and a piezoelectric patch 1008 that is attached to a structure 1010. The bridge circuit uses an input 1012 square wave clock signal instead of a sinusoidal wave as the input of the bridge circuit. If the bridge circuit were instead to use a sinusoidal wave as the input 1012 of the bridge circuit, the waveforms at points test points A 1014 and B 1016 would have phase differences causing the bridge circuit to not be balanced, due to the imaginary part of the electrical impedance of the piezoelectric patch 1008. The problem of phase differences would also greatly increase the complexity of other connected circuits. However, using a square wave clock signal as the input 1012 can eliminate this problem.

A piezoelectric patch 1008 can be modeled as a capacitor. When a capacitor is applied by a clock signal, it charges at the voltage level high and discharges at the voltage level low. The variation of capacitance reflects on the amplitude (peak value) and shape variations of the charge and discharge waveform. Therefore, using a clock signal and peak detectors at the output can detect the variations of the impedance of the piezoelectric patch 1008. When the bridge circuit is balanced, the value of the digital resistor 1006 equals the magnitude of the impedance of the piezoelectric patch 1008.

The digital resistor is a clock controlled variable resistor 1006, as shown in FIG. 10. From Eq. 4,

$$\frac{{R}_{1}}{{R}_{p}} = \frac{{R}_{2}}{\vert {Z}_{Piezo} \vert} \qquad ( 9 )$$

can be derived. Eq. 9 can be solved for Rₚ as:

$${R}_{p} = \frac{{R}_{1}}{{R}_{2}} \vert {Z}_{piezo} \vert \qquad ( 10 )$$

Because the impedance of the piezoelectric patch 1008 is much lower than the resistance of the digital resistor Rₚ 1006, in order to amplify the variations of the electrical impedance of the piezoelectric patch, R₁=2 kΩ and R₂=200Ω are chosen. The mean voltage applied to the piezoelectric patch 1008 is set to 1.5 V, since the piezoelectric patch 1008 requires low voltage to produce a high frequency excitation in the structure 1010.

The digital resistor Rₚ 1006 has a total of 128 distinct different resistance values ranging from 0Ω to 10 kΩ.

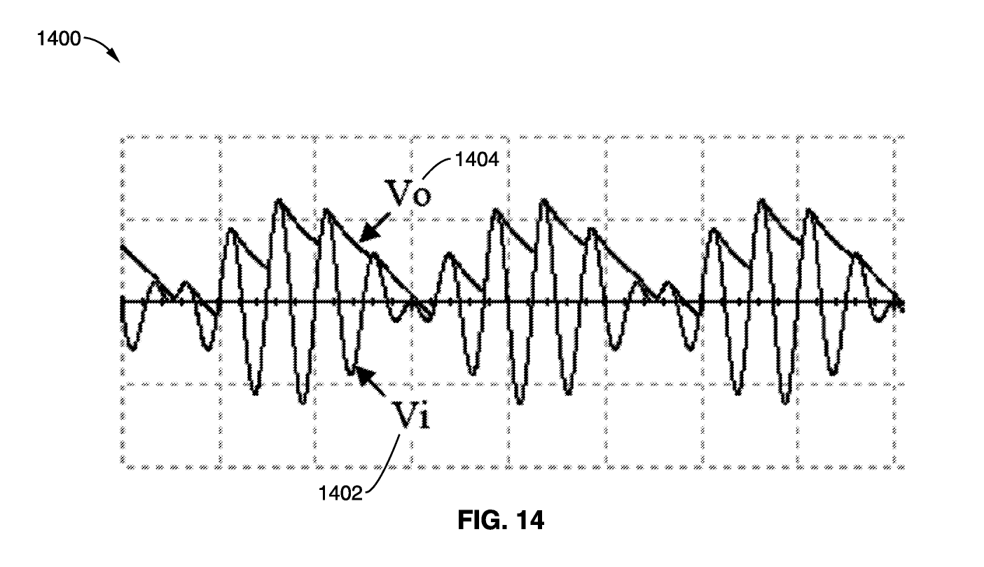

Refer now to FIG. 11, which is a graph 1100 of the percentage of total resistance versus the input count in the digital resistor Rₚ 1006. In this graph 1100 the lower portion 1102 of the scale advances 1% of the total resistance for each 3% of scale, providing precise adjustment. The upper portion 1104 of the scale advances 2% of the total resistance for every 1% of scale.

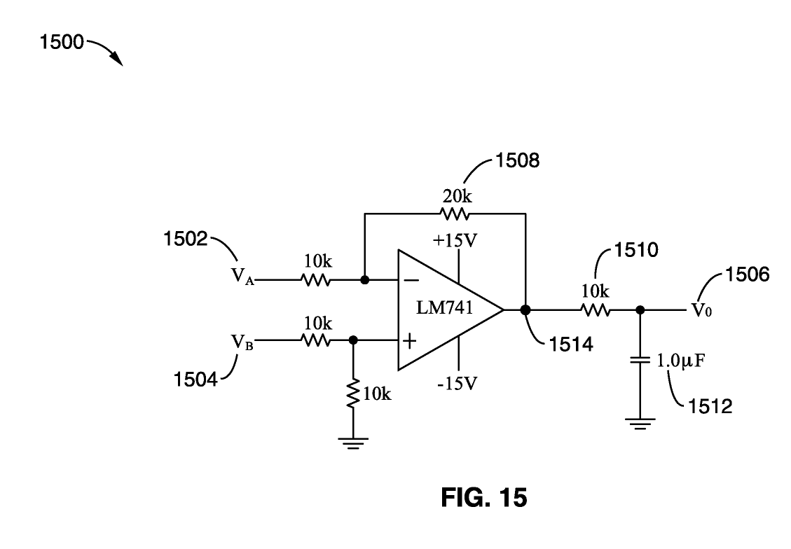

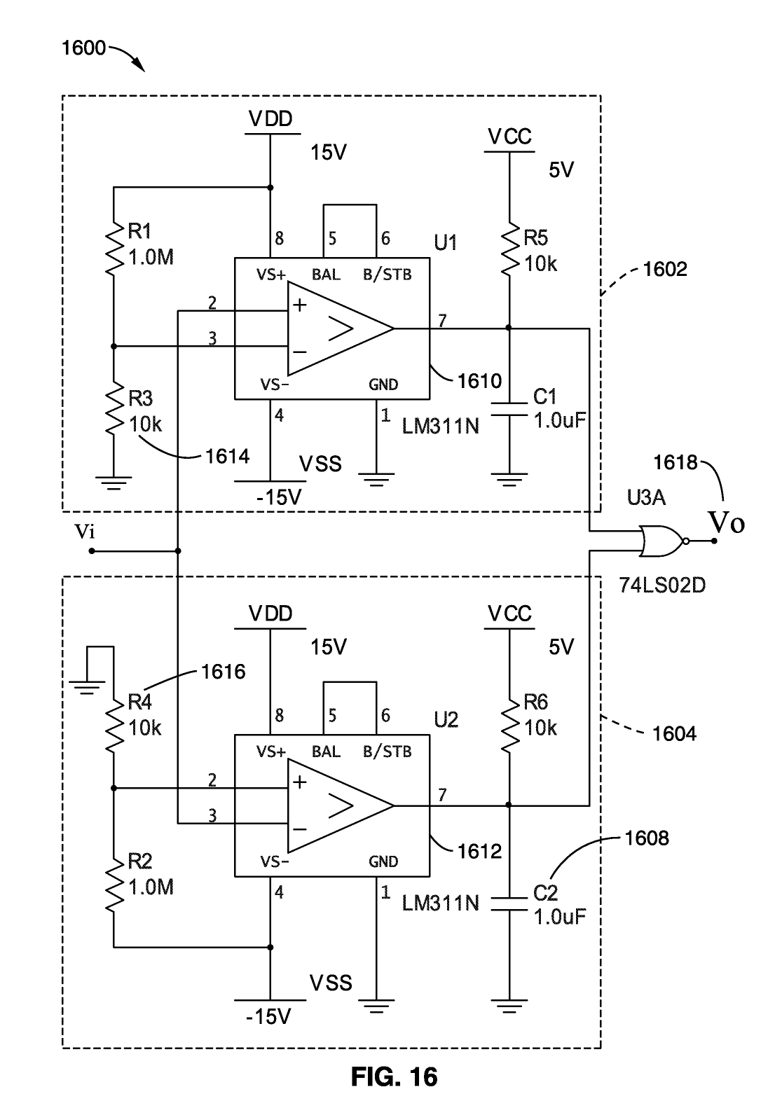

Refer now to FIG. 12A, which is a block diagram of the digital resistor Rₚ, and to FIG. 12B, which shows the pin connections of the digital resistor. A function table is shown below in Table 1 that details the operation of the 7 bit counter portion of the digital resistor. The 3-terminal port of the digital resistor provides an increment/decrement interface (U/ D̅) that is activated via a chip select input C̅S̅. The wiper movement control ( I̅N̅C̅) can be connected to a clock. Each falling edge of the clock moves the wiper position one step up/down.

From Eq. 10, if the ratio of R₂ and R₁ (R₂/R₁) decreases, the resistance of the digital resistor will increase. If the resistance of the digital resistor is higher than 2 kΩ, a more stable impedance curve can be obtained; however, the precision will be sacrificed. According to FIG. 12A, the lower half of the resistance of the digital resistor provides higher precision. Different piezoelectric patches have different characteristics impedances. In order to obtain better circuit performance, bridge circuit resistors R₁ and R₂ may need to be changed accordingly for different types of piezoelectric patches as necessary.

Those skilled in the art will appreciate that a digital capacitor could be substituted for the digital resistor in the bridge circuit.

Peak Detector

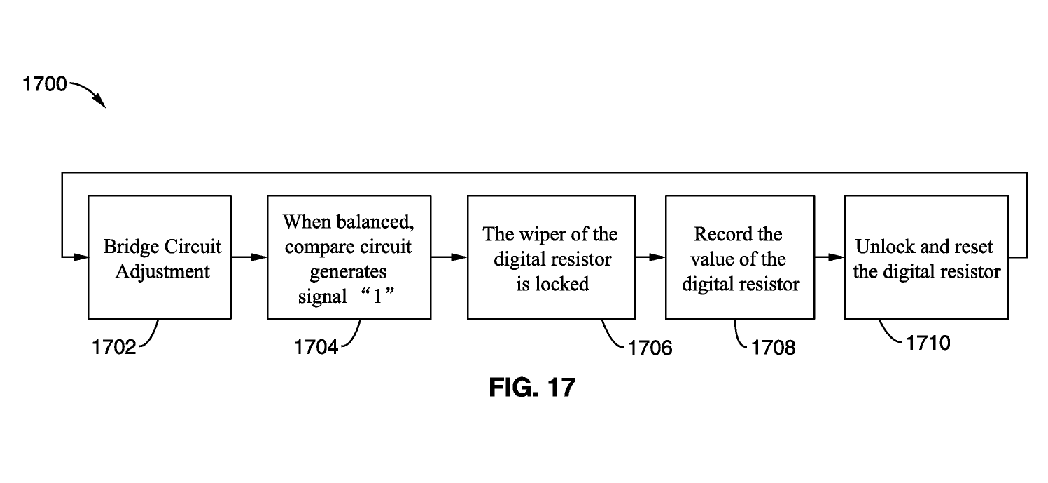

Refer now to FIG. 13, which is a schematic 1300 of the peak detector block. The peak detectors track the peak values of the input AC signals 1302 from the output of the bridge circuit. Because the impedance variations of the bridge circuit reflect on the amplitudes of the signals, the peak detectors can identify the impedance variations.

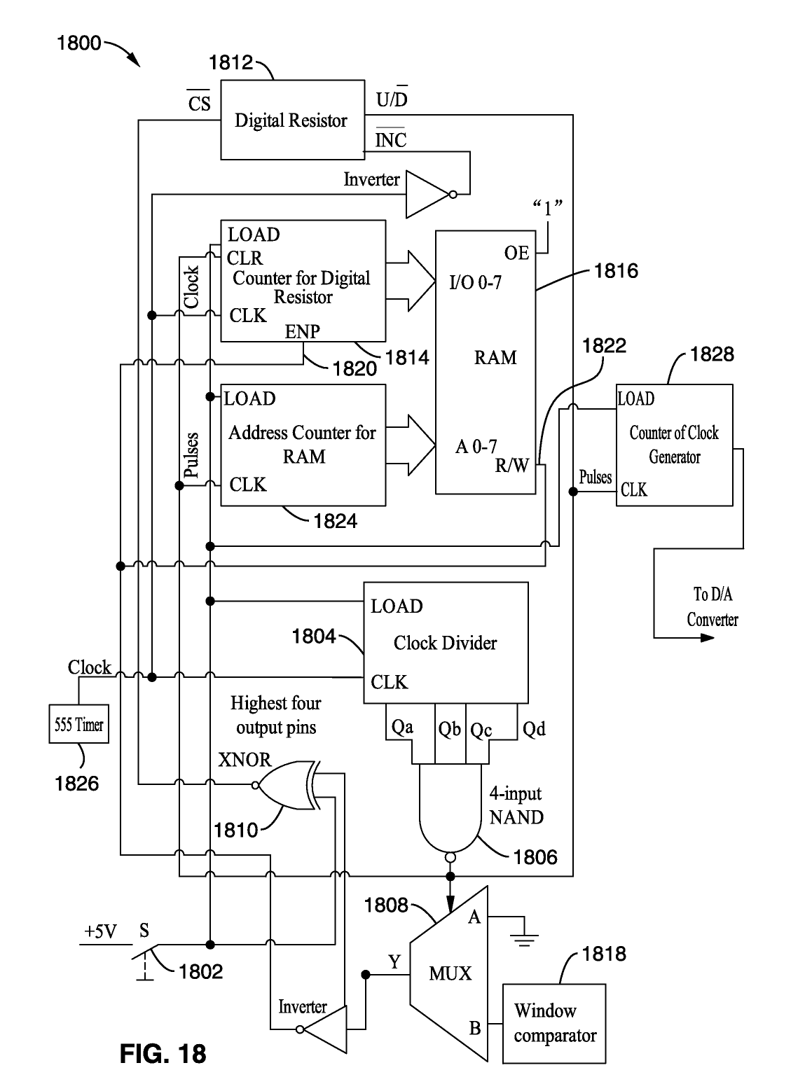

Refer now to FIG. 14, which is a simulation 1400 of the peak detector 1300 output 1304 is shown in FIG. 14. Specifically, here an input V 1402 results in a decaying envelope Vₒ 1404.

Differential Operational Amplifier

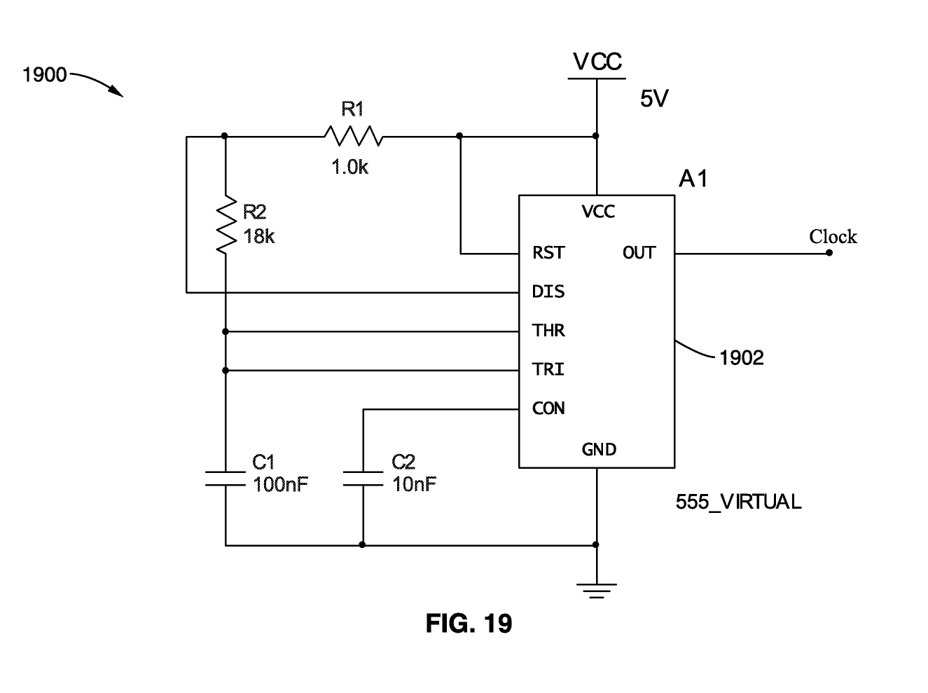

Refer now to FIG. 15, which is a schematic 1500 of the differential amplifier previously shown in FIG. 3. Also refer now to FIG. 3. After the peak detectors 306 and 308, a differential amplifier 310 is used to monitor the voltage differences between test point A and test point B of the bridge circuit 304. When V_{A} 1502 equals V_{B} 1504, the output voltage 1506 of the differential amplifier 1500 will be zero. Here, a feedback resistor 1508 uses 20 kΩ to amplify the signal by a factor of two for detailed impedance information. Larger feedback resistors provide larger signal amplifications, and still more precise information from the piezoelectric patch may be obtained. However, the smaller feedback resistor provides enhanced stability, because smaller signals are easier for the window comparator to identify whether or not the bridge circuit 304 is balanced.

An RC low pass filter comprising a 10 kΩ 1510 and 1.0 μF 1512 is connected to the output 1514 of the differential amplifier to remove noise. The output 1506 of the low pass filter is used as the input to the window comparator 312.

As shown in FIG. 3, peak detectors 306 and 308 are located before the differential amplifier 1500. The amplitudes of the voltages at test points A and B of the bridge circuit 304 can be obtained, as well as the difference between the two points. This can provide more precise information about the voltage amplitude difference between test points A and B.

Window Comparator

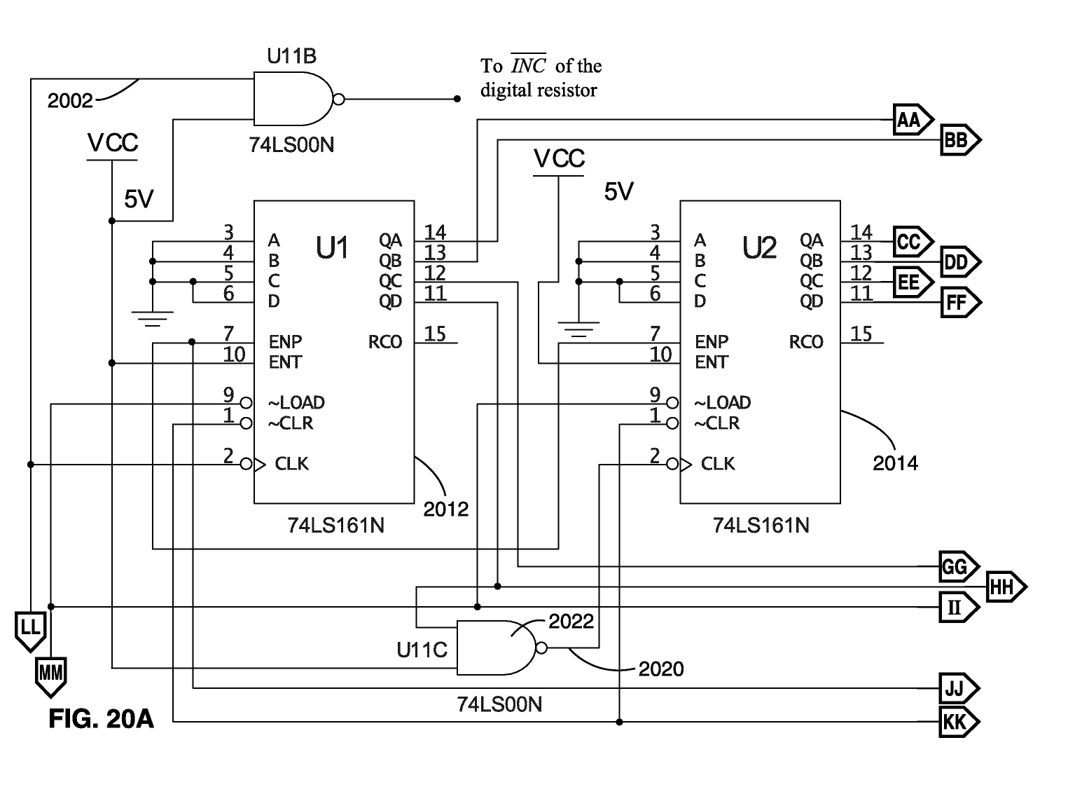

Refer now to FIG. 16, which is a schematic of a window comparator 1600. The window comparator 1600 identifies whether or not the bridge circuit is balanced and generates a digital signal of “0” for the unbalanced bridge circuit and “1” for the balanced bridge circuit. The output signal is subsequently used by the control circuit. The output of the differential amplifier 1500 low pass filter 1506 (previously discussed in FIG. 15) is used as one input to two comparators (LM311) 1602 and 1604. Capacitors C₁ 1606 and C₂ 1608 are for stability. An output logic table from the window comparator 1600 is shown in Table 2. When Vᵢ is greater than +150 mV, the output of comparator 1 (U1) 1610 is “1” (voltage level high), and the output of comparator 2 (U2) 1612 is “0” (voltage level low). Thus, Vₒ will be “0”. When Vᵢ is less than −150 mV, the output of comparator 1 1602 is “0”, and the output of comparator 2 1604 is “1”. Therefore, Vₒ will be “0”. The bridge circuit is only balanced when the value of Vᵢ is between −150 mV and +150 mV. When the outputs of comparator 1 1602 and comparator 2 1604 are both “0”, then Vₒ is “1”, which can be used to hold the value of the digital resistor. The value of the digital resistor Rₚ in the bridge circuit can be found out. In the window comparator, the higher resistances of R₃ 1614 and R₄ 1616 provides greater stability, however, lower resistances of R₃ and R₄ can provide greater precision.

Once the bridge circuit is balanced, the output of the window comparator 1600 generates a “1” signal, which will hold the value of the digital resistor Rₚ. There is no reset pin in the digital resistor. If Vₒ 1618 of the window comparator 1600 is directly used as the chip select signal C̅S̅ of the digital resistor Rₚ (see FIGS. 12A and 12B) directly, the wiper of the digital resistor Rₚ will be locked all the time and the value of the digital resistor Rₚ will not change as long as the bridge circuit is balanced. However, the digital resistor Rₚ has to be reset before the next measuring process starts. A control circuit is needed to generate a signal that can unlock the wiper of the digital resistor Rₚ after the value of the digital resistor Rₚ has been recorded.

Control Circuit

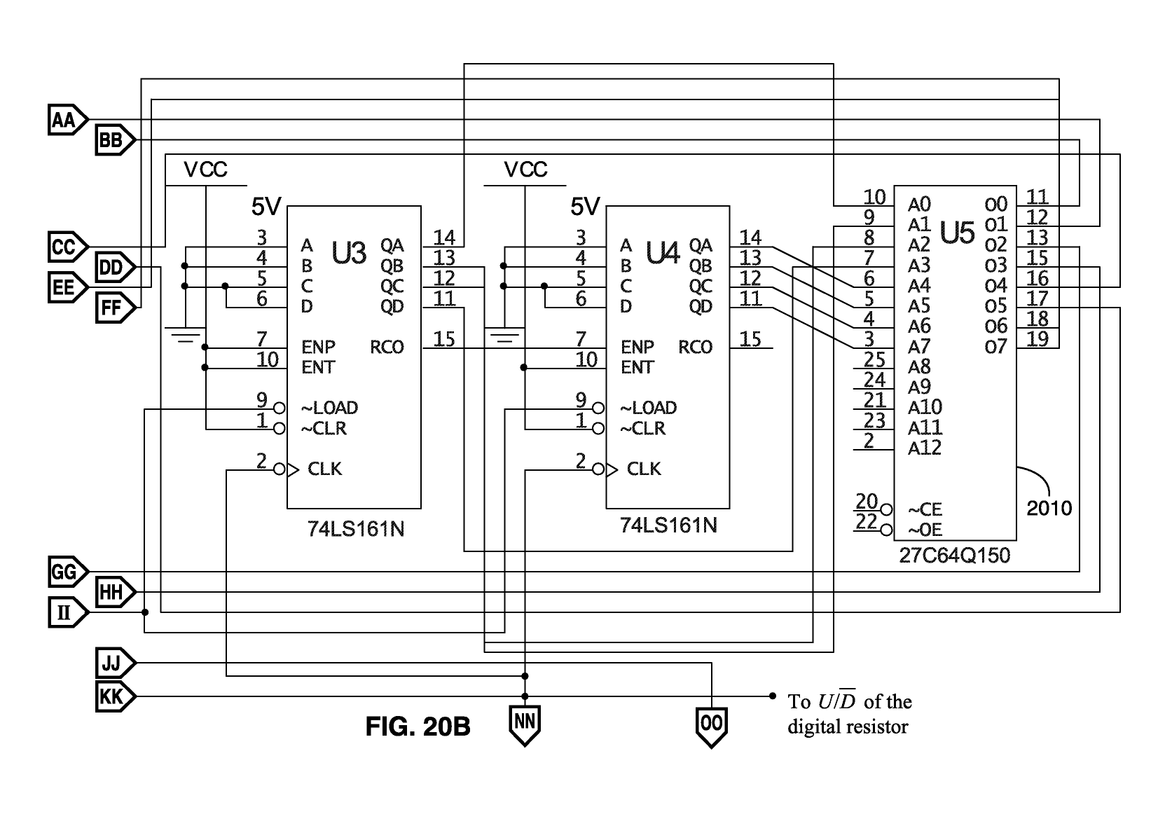

Refer now to FIG. 17, which shows a state flow diagram for the digital resistor Rₚ control circuit 1700. Initially, the bridge circuit has digital resistor Rₚ adjusted 1702. When the bridge is balanced, the window comparator circuit 1704 outputs a logical “1” value. When the logical “1” value is sensed, the wiper of the digital resistor Rₚ is locked 1706. At this point, the value of the digital resistor Rₚ is read and recorded 1708. Then the digital resistor Rₚ is unlocked and reset 1710, which leads back to adjusting the bridge circuit 1702.

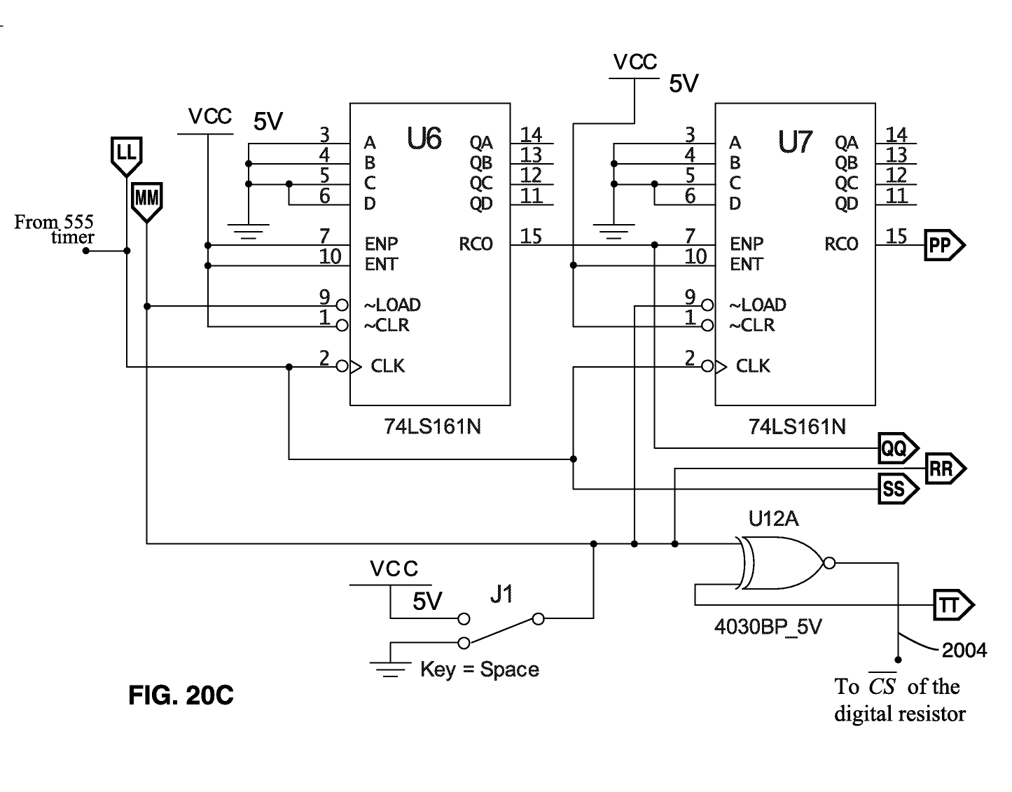

Refer now to FIG. 18, which is a schematic of one embodiment of the control circuit used to hold and record the value of the digital resistor and the clock generator 1800. Once the data has been recorded, the control circuit will generate a signal to reset the digital resistor and increase the frequency of the clock generator to repeat the measuring cycle.

When the power is on, the initial setting of the switch S 1802 is “0”. All the counters are reset and the outputs of the counters are all “0”. At this time, because the bridge circuit is unbalanced, the output of the window comparator is “0”, and Q_{A}, Q_{B}, Q_{C}, and Q_{D} (the highest four output pins of the clock divider) 1804 are all “0”. Through a 4-input NAND gate 1806, the U/ D̅ of the digital resistor is “1”, the CLR of the counters is “1”, and the MUX (multiplexer) 1808 always selects B. Through an XNOR gate, 1810 the C̅S̅ of the digital resistor is “1”, and the wiper of the digital resistor 1812 is locked. This will ensure that the digital resistor 1812 and all the counters start from “0”.

When the switch S 1802 is switched to “1”, the C̅S̅ of the digital resistor 1812 is “0”, and the bridge circuit is unbalanced. The value of the digital resistor 1812 increases one step when each falling edge of the clock arrives. Meanwhile all the counters start to count. The counter for the digital resistor 1814 and the digital resistor 1812 share the same clock (Clock). The counter for the digital resistor 1814 can indicate how many steps that the digital resistor 1812 has increased. The value of the digital resistor 1812 can be obtained through reading the output of the counter for the digital resistor 1814. All the measurements can be recorded in a memory chip (RAM) 1816.

When the bridge circuit is balanced, the output of the window comparator 1818 is “1”, and the enable signal ( E̅N̅P̅) 1820 of the counter for the digital resistor 1814 is “0”. The counter for the digital resistor 1814 stops counting and holds the value. At this time, the read/write signal (R/ W̅) 1822 of the RAM 1816 is “0” and the RAM 1816 accepts data from the counter for the digital resistor 1814 to the address “00000000”. The clock divider 1804 will keep counting. Before Q_{A}, Q_{B}, Q_{C}, and Q_{D} are all “1”, enough time has elapsed for the RAM 1816 to access the data from the counter for the digital resistor 1814.

When Q_{A}, Q_{B}, Q_{C}, and Q_{D} are all “1”, the multiplexer 1808 selects A, which is “0”, the RAM stops writing, the E̅N̅P̅ of the counter for the digital resistor is “1”, and the wiper of the digital resistor 1812 is unlocked. At this time, the U/ D̅ of the digital resistor 1812 is “0”, and the CLR of the counters is “0”. The output of the counter for the digital resistor 1814 is cleared to “0”. The output value of the clock divider 1804 changes from “1111100000000” to “000000000000”. This time is sufficient for the digital resistor 1812 to be able to count down to its lowest value (initial value).

When Q_{A}, Q_{B}, Q_{C}, and Q_{D} are all “0”, the multiplexer 1808 selects B, the U/ D̅ of the digital resistor 1812 is “1”, the CLR of the counters is “1”. The address counter 1824 for the RAM 1816 and the counter of the clock generator 1828 add “1”. Then, the counter of the clock generator 1828 will sweep to the next clock frequency, and the whole system will begin a new measurement process.

The clock signal (pulses) which is used in the clock generator is derived from the output of a 4-input NAND gate (74LS20) 1806.

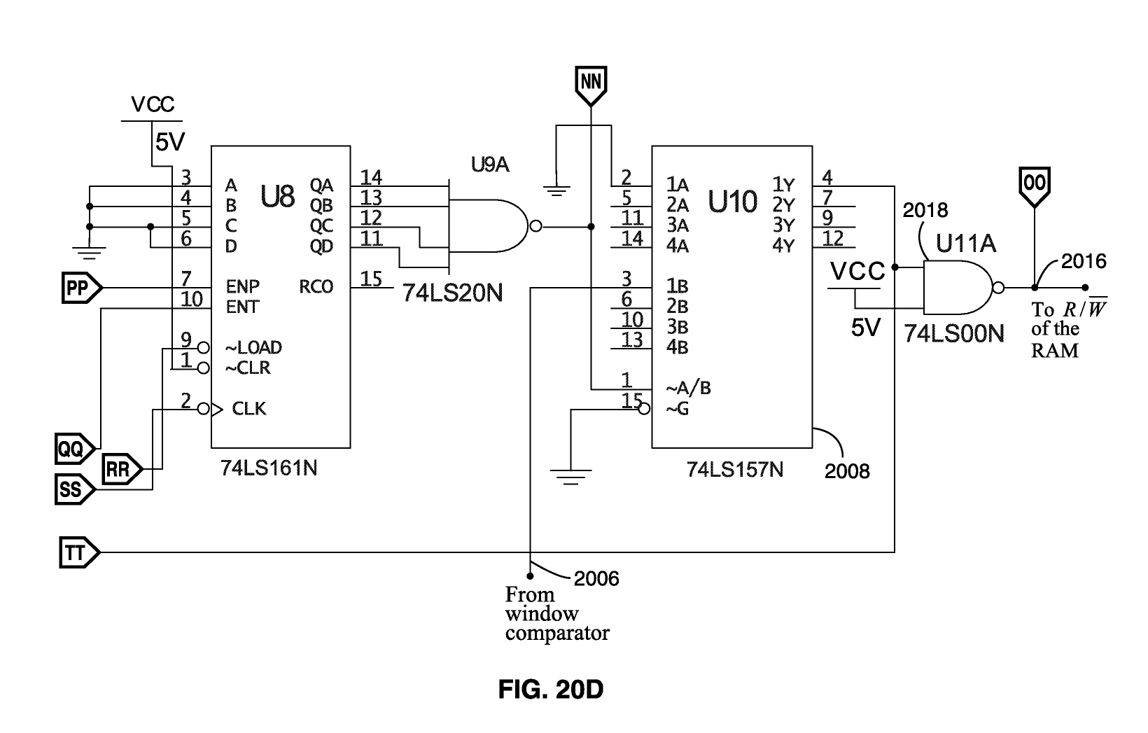

Refer now to FIG. 19, in a schematic 1900 which shows an implementation of a 555 timer configured to generate a clock signal (Clock) of about 386 Hz.

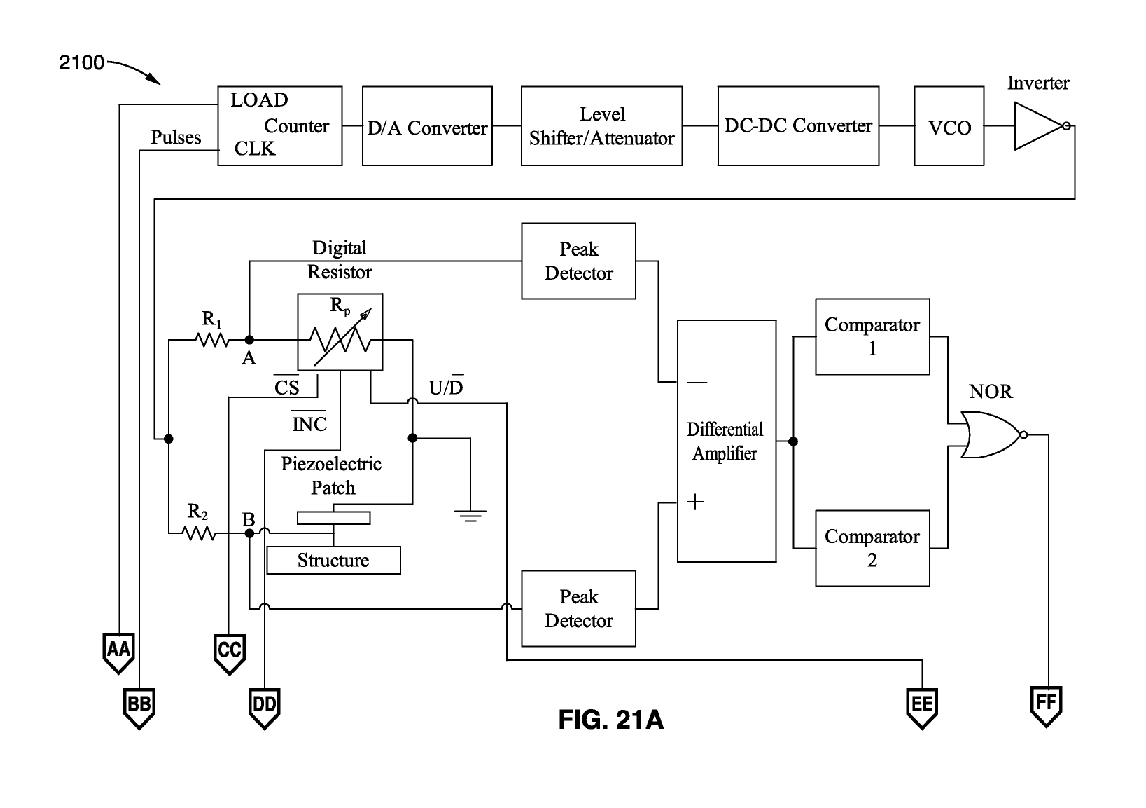

Refer now to FIG. 20, which is a schematic of one embodiment of the control circuit 2000. The output of the NAND gate (U11B) 2002, which should be connected to the wiper movement control signal I̅N̅C̅ of the digital resistor, is floating. The output of the XNOR gate (U12A) 2004, which should be connected to the wiper movement enable signal C̅S̅ of the digital resistor, is floating. Input 1B 2006 of the multiplexer (U10) 2008, which should be connected to the output of the window comparator is floating. Memory 27C64Q150 (U5) 2010 instead of HM6264 RAM is for brief in this schematic.

The interconnection of counters U1 2012 and U2 2014, is different from other interconnections of counters in this circuit. The E̅N̅P̅ of U2 2014 is connected to the E̅N̅P̅ of U1 2012. Both of the E̅N̅P̅ signals are controlled by the output 2016 of the NAND gate (U11A) 2018. The clock of U2 derives from the highest digital output of U1 2012 through the output 2020 an inverter 2022. Both U1 and U2 will be locked together.

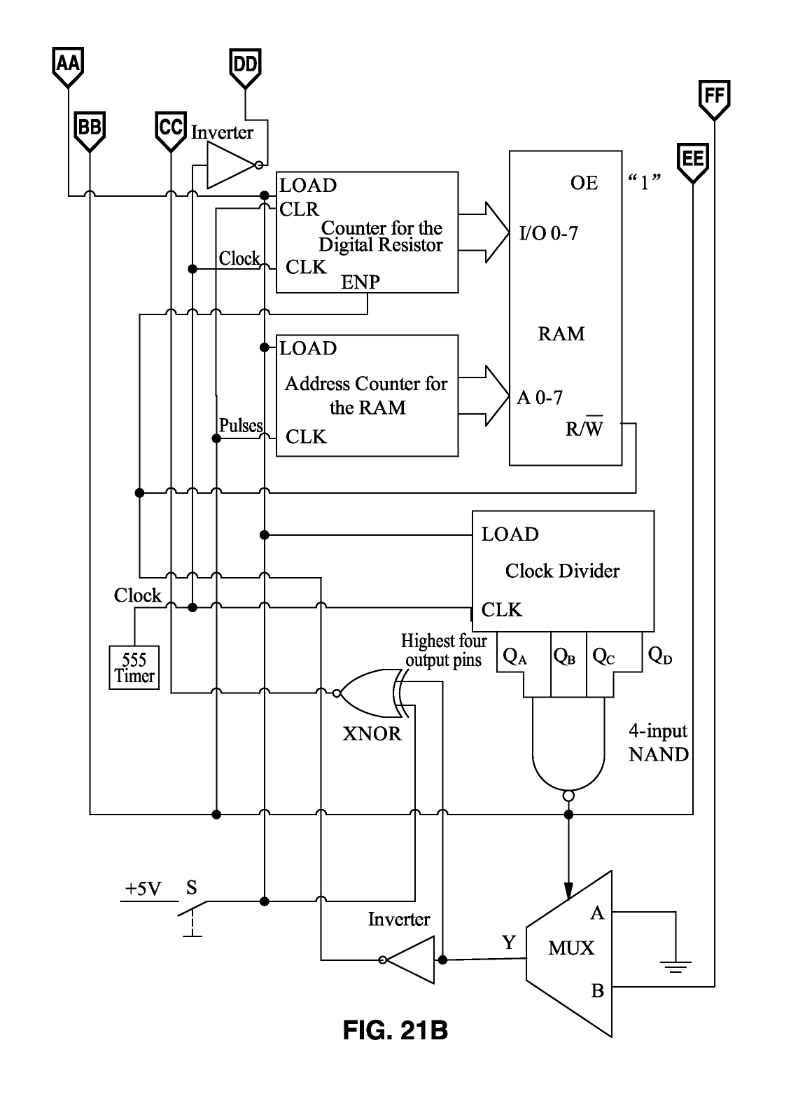

Refer now to FIG. 21, which is an exemplary detailed block diagram of the entire structural health monitoring circuit 2100. FIG. 21 shows the entire system comprised of the components and subsystems previously described in FIGS. 1-20.

### Experimental Validation

An aluminum plate and a wood plate are objects of measurements taken by the structural health monitoring circuit described above. In general, one represents a conductor, and the other one represents an insulator. They have different characteristics of impedance. The reason for using these materials is to demonstrate that the circuit can be used with a comprehensive collection of materials.

### Experimental Setup

The impedance-based structural health monitoring circuit was realized on breadboards for initial testing and circuit performance testing. National Instruments LabVIEW NIDAQ software was used with an associated National Instruments digital input output (DIO) device substituted instead of the on-board RAM that would have been used instead in the stand-alone structural health monitoring circuit. A personal computer (PC) was used to collect data with LabVIEW accessing the DIO device. The resulting data was plotted as curves with the PC.

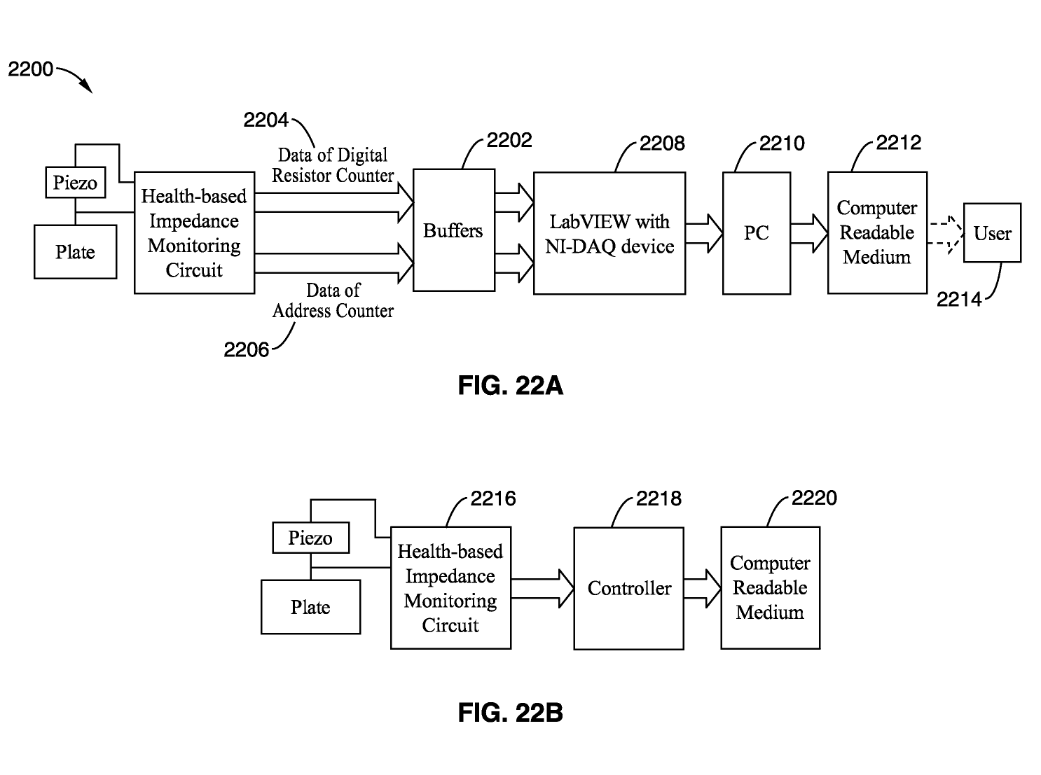

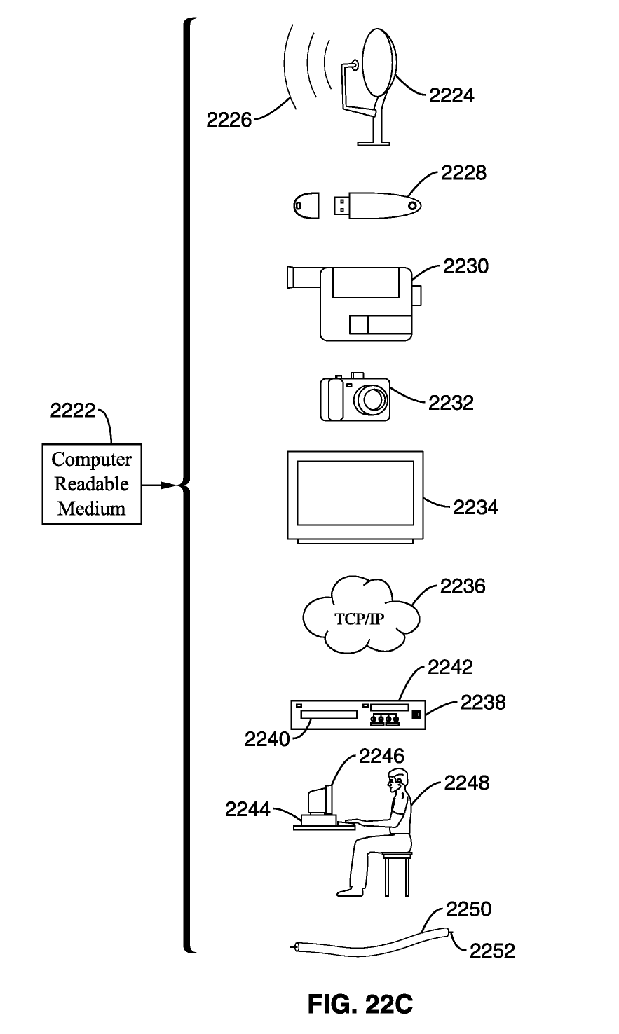

Refer now to FIG. 22A, which shows an exemplary block diagram 2200 of the experimental setup for the LabVIEW system. Buffers 2202 were added at the outputs of the digital resistor counter 2204 and the address counter 2206 for stability and improved isolation. During measurement, current may sink into the NI-DAQ device 2208, which may pull down the output voltage of counter because the NI-DAQ device uses analog circuitry. In addition, because the output voltage of the impedance-based structural health monitoring circuit is derived from digital components, buffers were used to avoid noise interference between the analog and digital circuits.

The NI-DAQ device 2208 is connected to a computer 2210, which may output some portion, or all, of the data obtained from the health-based impedance monitoring circuit to a computer readable medium 2212. This data may then be evaluated or used in some fashion by a User 2214.

While FIG. 22A shows only a LabVIEW implementation of the health-based impedance monitoring circuit, the output data from the circuit may be either directly output to a computer readable medium, or to a computer controller that outputs either all, or some redacted portion of the output data to a computer readable medium.

Refer now to FIG. 22B, which is a block diagram of a more portable implementation of a system using the health-based impedance monitoring circuit 2216. Here, a controller 2218 interacts with the health-based impedance monitoring circuit 2216 to produce data stored on a computer readable medium 2220. As this may be implemented with very low power microcontrollers, such a unit may be very small, and very inexpensively produced.

Refer now to FIG. 22C, which is a diagram of the various computer readable media 2222 that may be used as output. Here, data from the portable system of structural health monitoring of FIG. 22B may be sent to a microwave transmitter 2224 for propagation through microwaves 2226 to a distant connection. Similarly, and not shown, the data may be transmitted to remote receivers. The data may be stored on a memory device faster or slower than the depicted USB storage device 2228, as well as stored on a digital or analog recording medium exemplified as a high definition video recorder 2230, or a still or moving digital camera 2232. Similarly, the data may be displayed, with or without further processing, on a graphical device such as a plasma or liquid crystal display 2234. The data may be transmitted through a network 2236, which may be wireless, or may use TCP/IP or other interconnection techniques to any other device in this FIG. 22C. Still another output of the data may be to a multiple media device 2238, which may have a VHS video recorder 2240, or a DVD recorder 2242. Yet another output of the data may be to a computer 2244 that may or may not be connected to a display device 2246, to be ultimately viewed by a person 2248. The computer 2244 may itself have a wide variety of computer readable media available for subsequent secondary output of the data. Finally, the data may be transmitted through a wired connection 2250, which may have one or more conductors 2252 of electromagnetic information, ultimately being transmitted to one or more of the devices present in this FIG. 22B.

### Experimental Results

### 1. Aluminum Plate

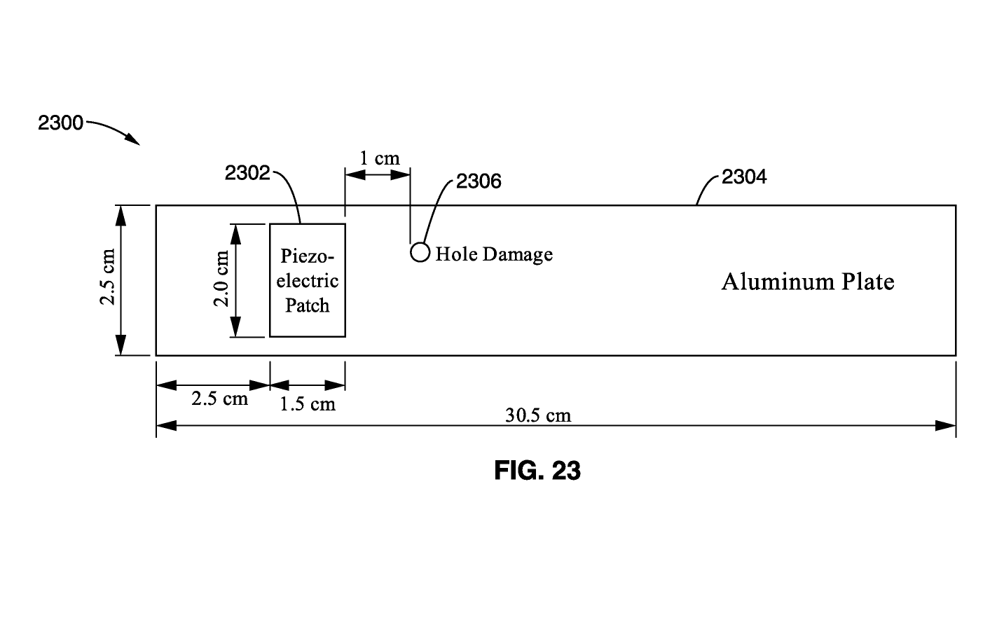

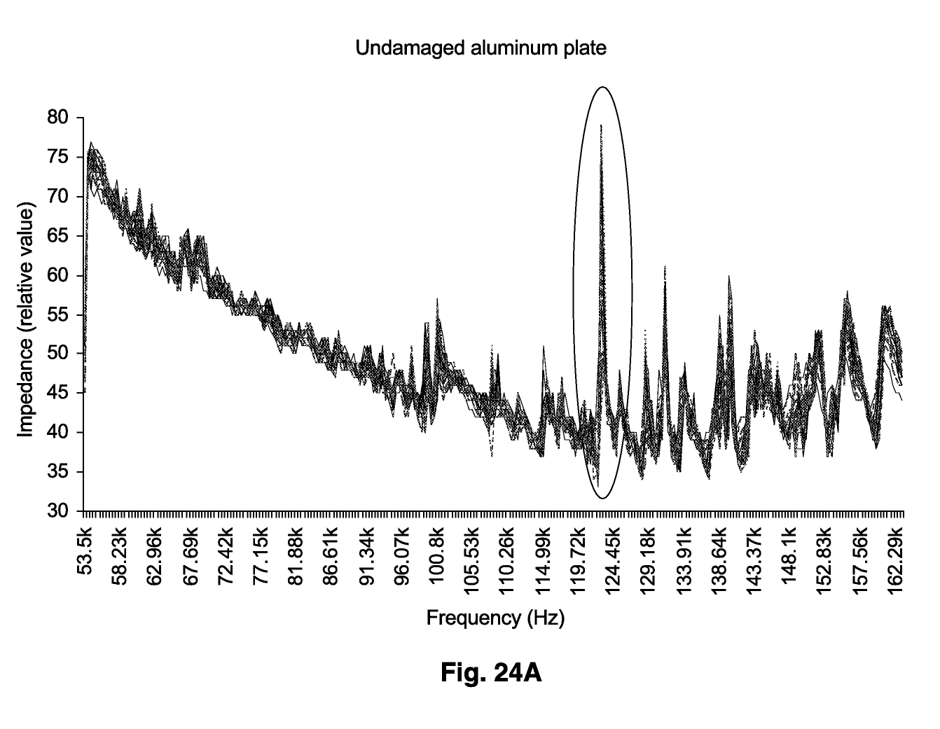

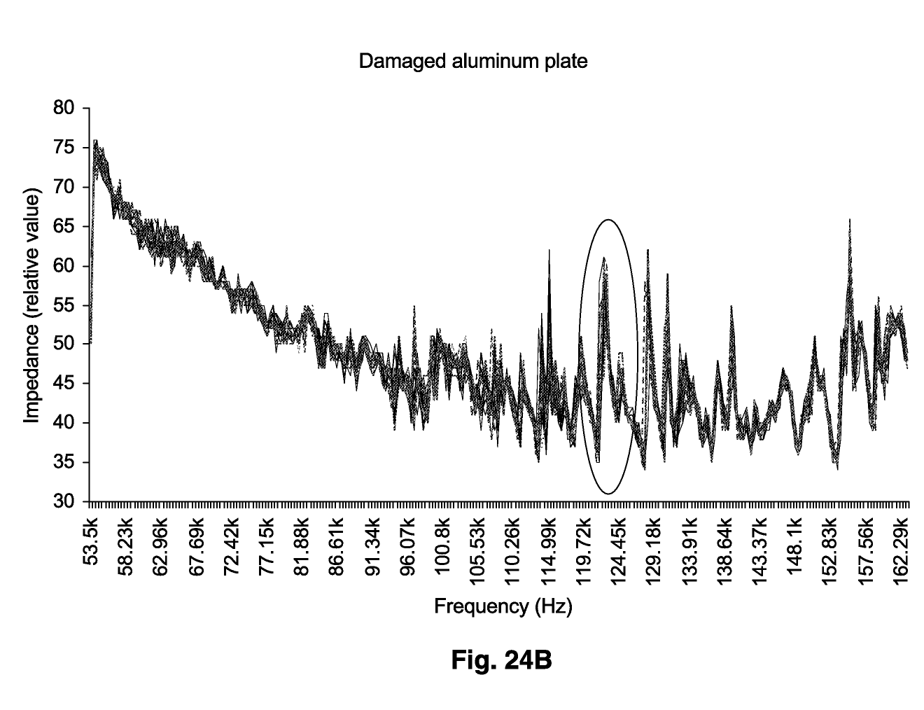

Refer now to FIG. 23, where a test setup 2300 with a piezoelectric patch 2302 (1.5×2.0×0.02 cm³) was attached to an aluminum plate 2304 (2.5×30.5×0.2 cm³). The impedance an undamaged plate was initially measured. The impedance of a damaged plate (where one 3 mm diameter hole 2306 was drilled on the aluminum plate) was measured. The results were compared. Undamaged and damaged aluminum plates impedance-frequency curves are respectively shown in FIGS. 24A and 24B.

Refer now to FIGS. 24A and 24B, which are plots of impedance versus frequency for the respective undamaged and damaged plate. There are 30 series of data in each of the two curves.

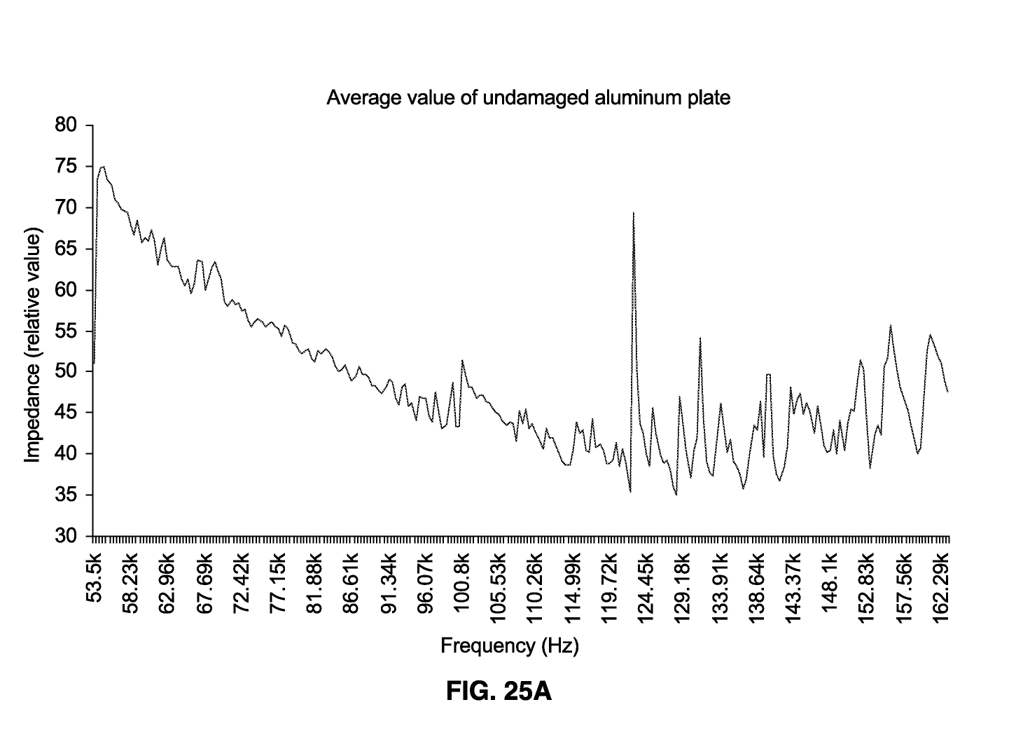

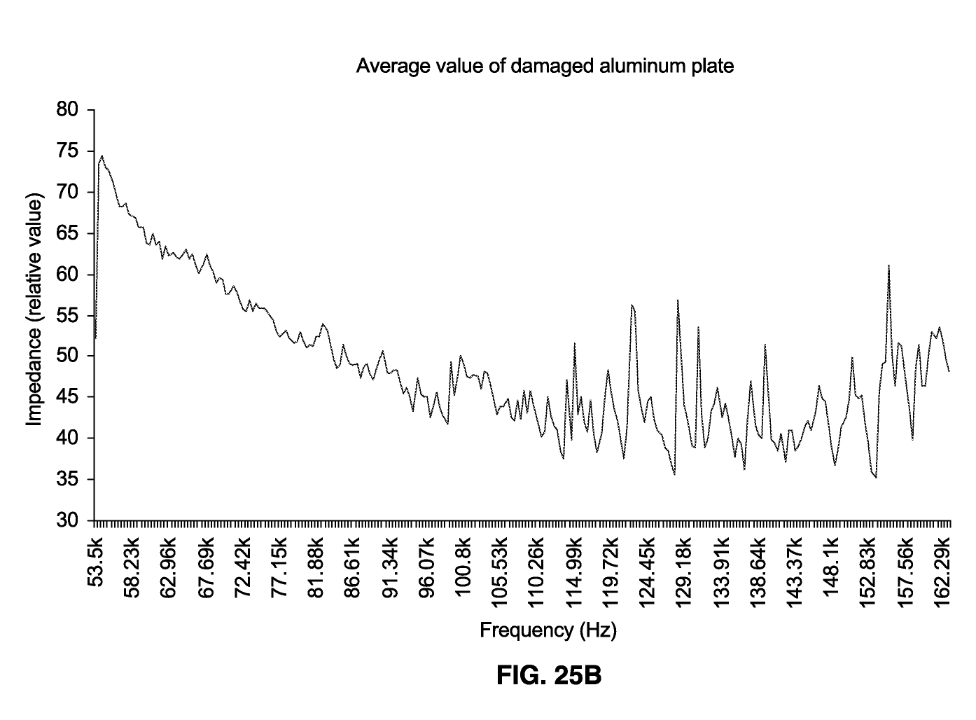

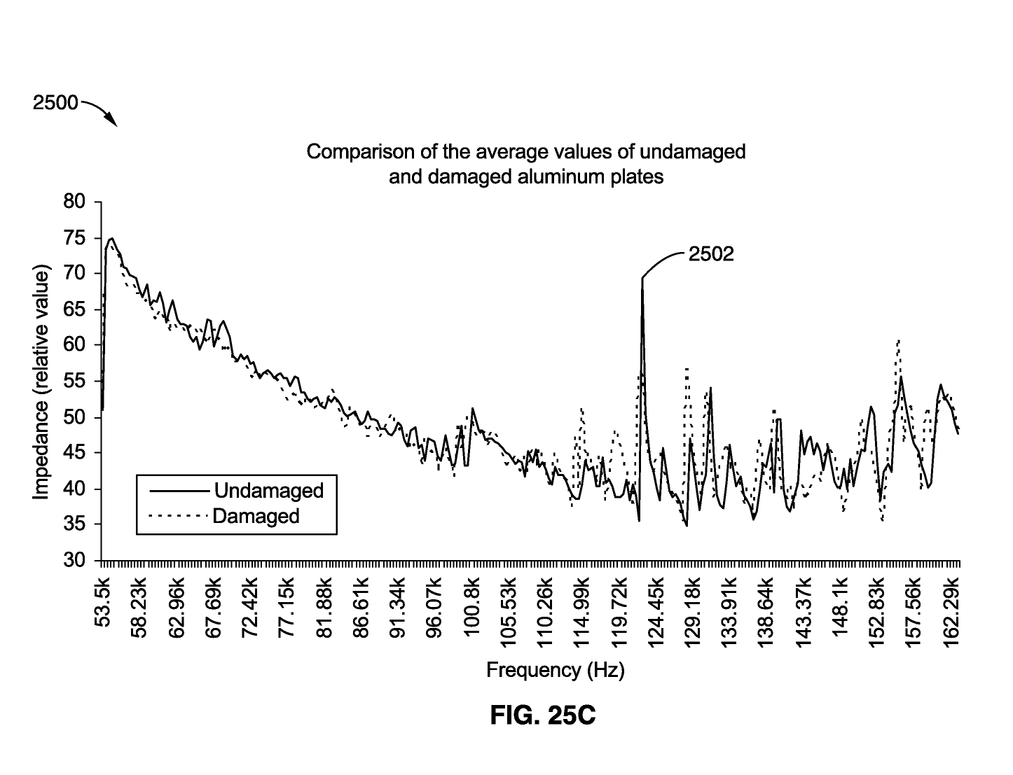

Refer now to FIGS. 25A and 25B, which compare the average values of undamaged and damaged aluminum plate's impedance-frequency curves shown respectively in FIGS. 24A and 24B. The impedance modulus value, which is read from the output of the digital counters, is a relative value, not an absolute value. These curves were only compared qualitatively, not quantitatively.

Refer now to FIG. 25C, which is an overlay 2500 of the plots of FIGS. 25A and 25B. Here, it is apparent that the magnitudes and locations of resonant peaks were changed because of the damage. These can be considered to be the main difference between the undamaged and damaged aluminum plates. For example, the most prominent change 2502 appeared as a resonant peak at about 123 kHz.

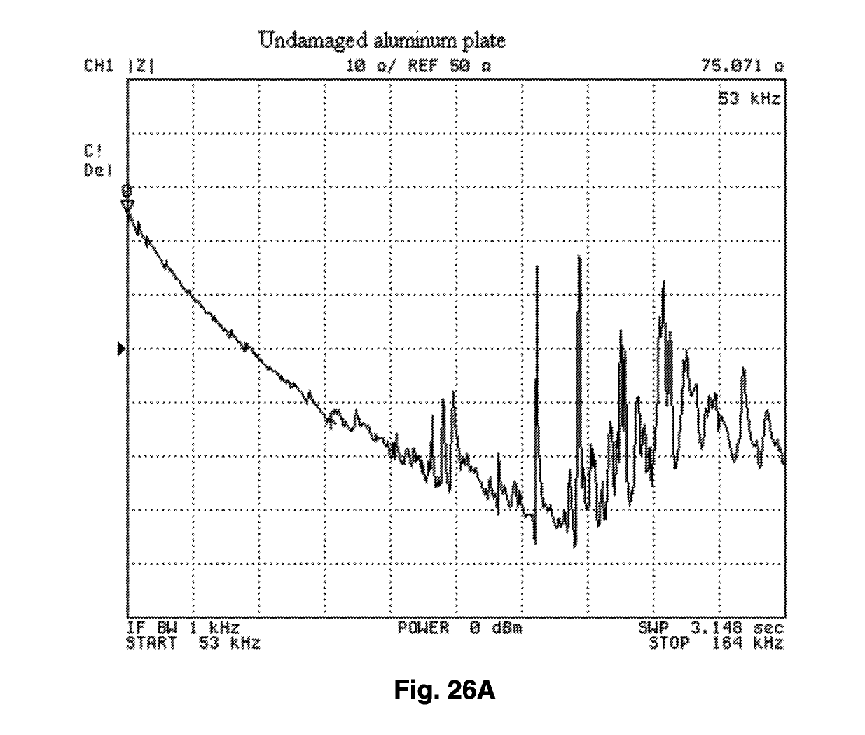

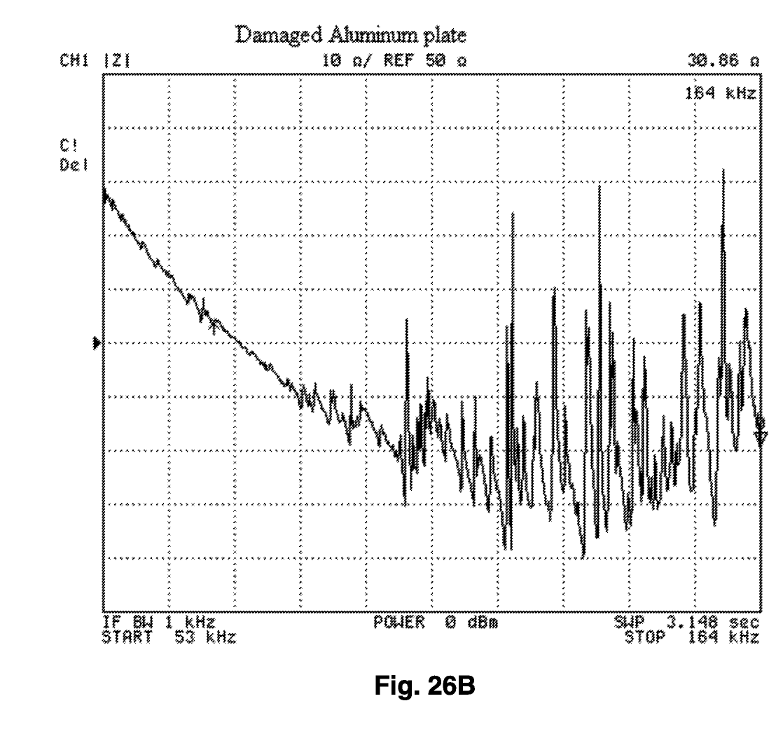

Refer now to FIGS. 26A and 26B, where impedance versus frequency curves of the piezoelectric transducer are plotted by an Agilent 4395A impedance analyzer for the undamaged and damaged aluminum plates, respectively. This analysis tends to verify the circuit operation, as magnitude and location changes of resonant peaks consistent with those found in FIGS. 25A and 25B were similarly observed.

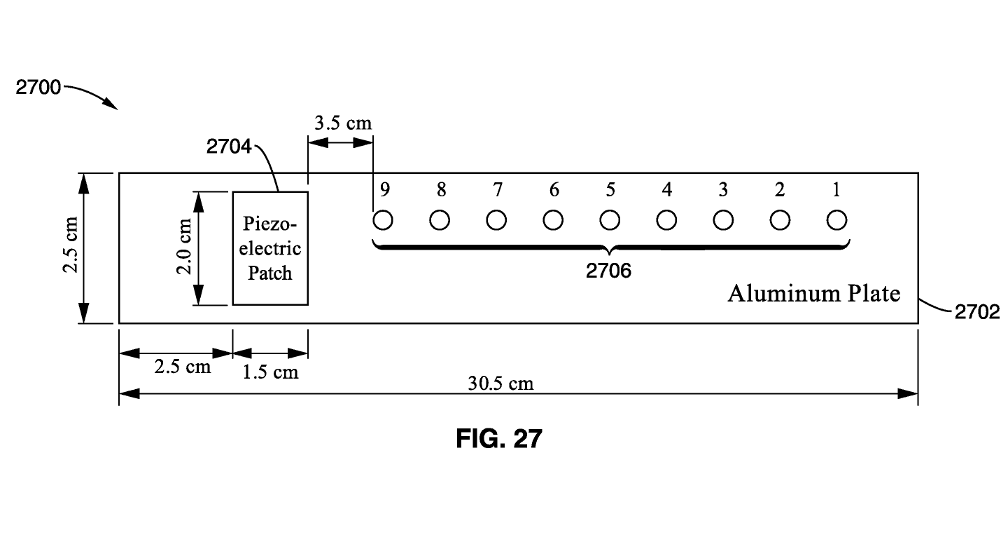

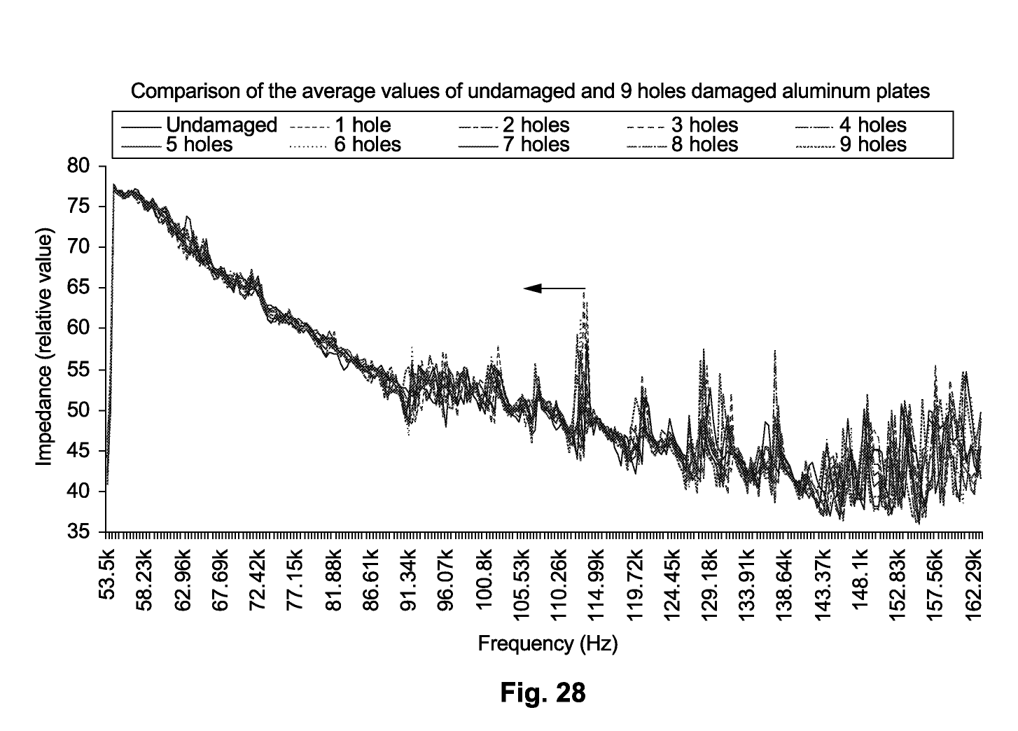

FIG. 27 shows another experimental setup 2700 to determine the piezoelectric sensing range in an aluminum plate 2702. Here, a piezoelectric patch 2704 (1.5×2.0×0.02 cm³) was attached to the aluminum plate 2702 (2.5×30.5×0.5 cm³). The impedance of an initially undamaged plate 2702 was measured. Then, nine 3 mm diameter holes 2706 were drilled continuously from one side of the aluminum plate towards one edge of the piezoelectric patch. The distance between two holes was 2.5 cm. After each hole was drilled, the electrical impedance of the piezoelectric patch was measured. The impedance-frequency curves of the undamaged and 9 holes damaged aluminum plates are shown in FIG. 28.

Refer now to FIG. 28, which shows the plot of impedance versus frequency after each of the holes is sequentially drilled in the aluminum plate of FIG. 27. Each curve is an average value of 30 sets of acquired series data. There appears to be only small differences until the third hole was drilled. From the third hole, the resonant peak at 113 kHz begins to shift towards lower frequencies. Although this is a very busy plot, it may be concluded the sensing range of one piezoelectric patch in the aluminum plate in this experiment appears to be about 18.5 cm in distance.

### 2. Wood Plate

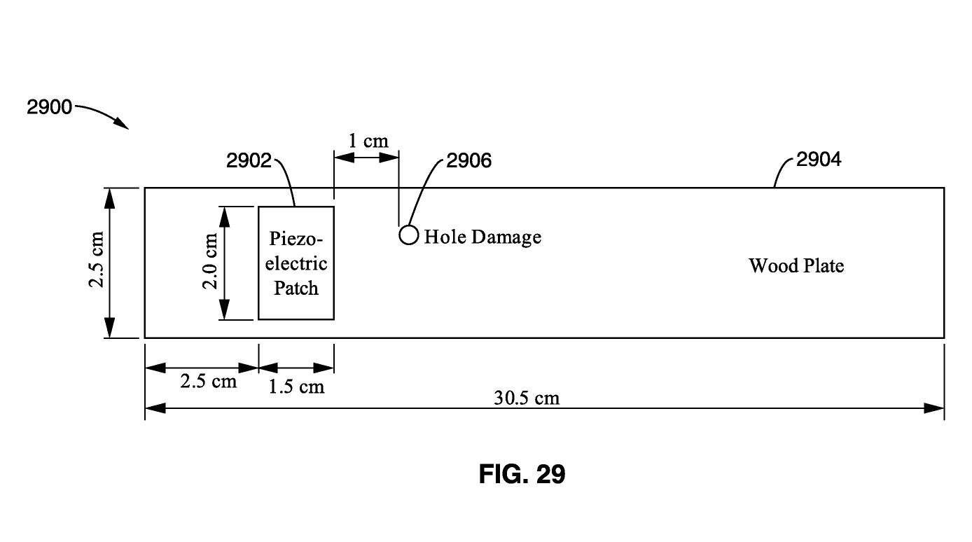

Refer now to FIG. 29, where a test setup 2900 is comprised of a piezoelectric patch 2902 (1.5×2.0×0.02 cm³) attached to a wood plate 2904 (2.5×30.5×0.5 cm³). The impedance of the undamaged plate (no holes on the wood plate) was measured. Then the impedance of the damaged plate (one 3 mm diameter hole 2906 drilled in the wood plate) was measured. The results were compared.

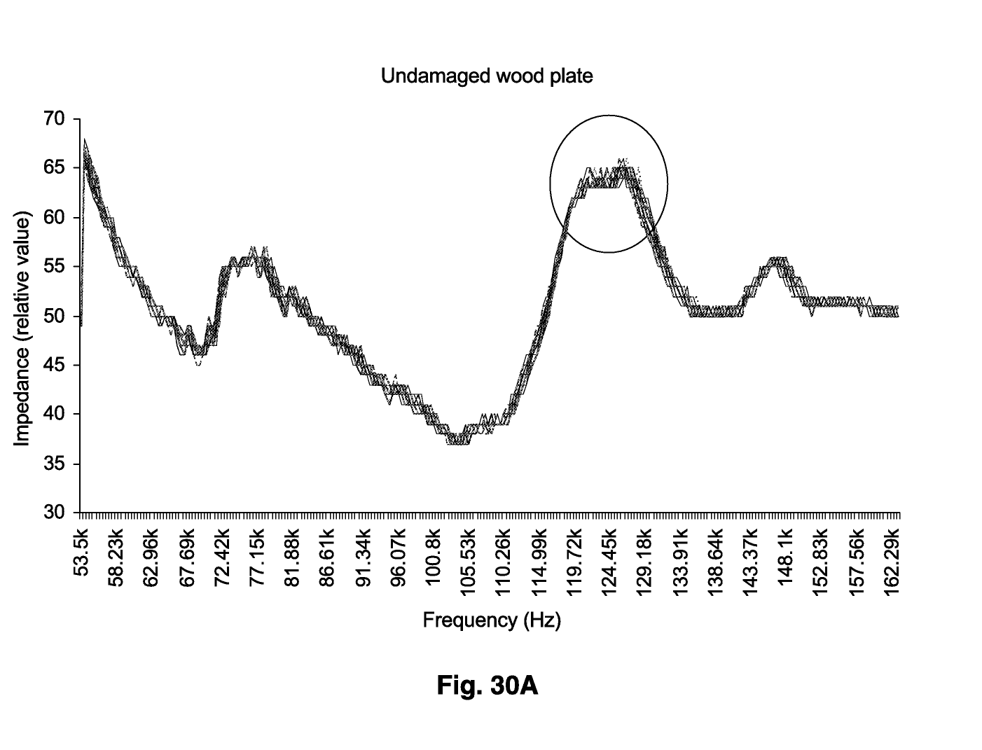

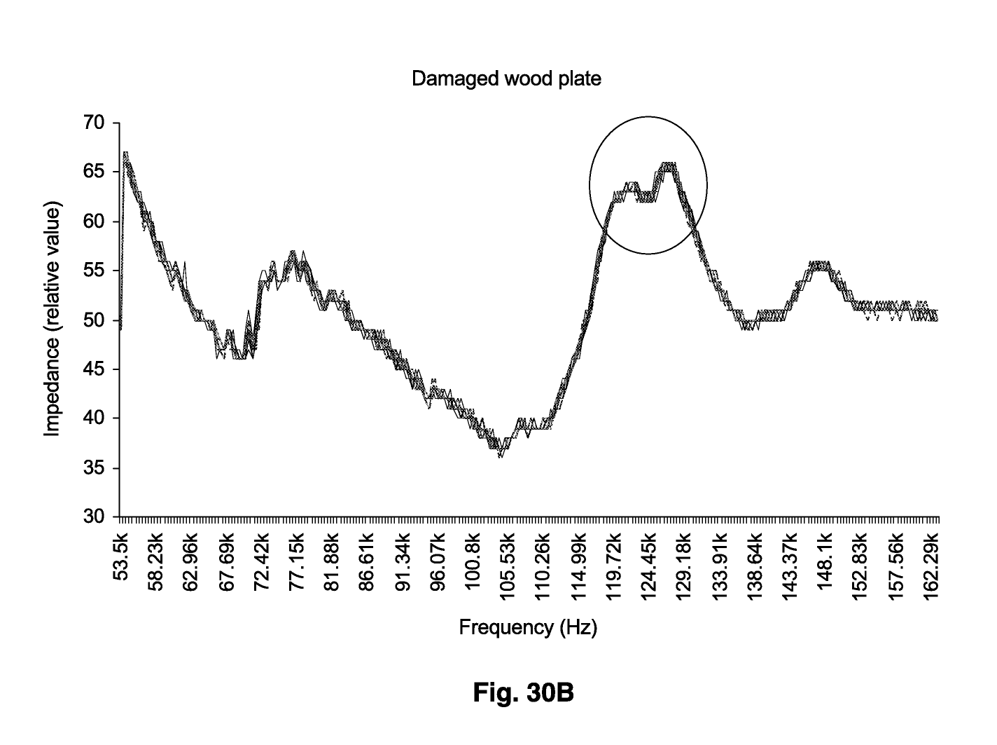

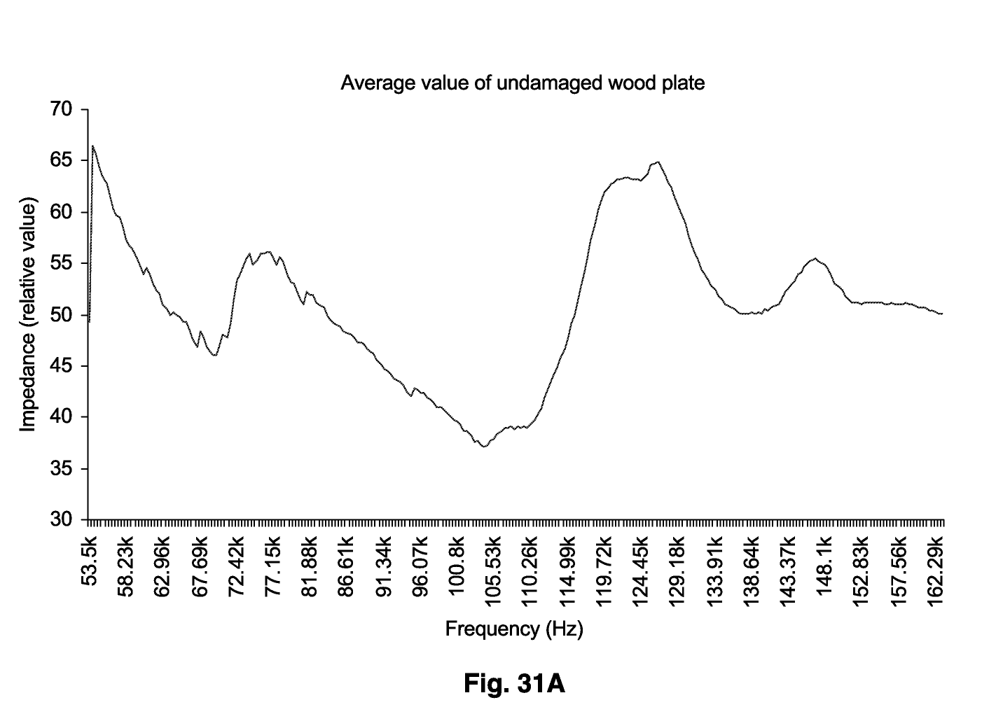

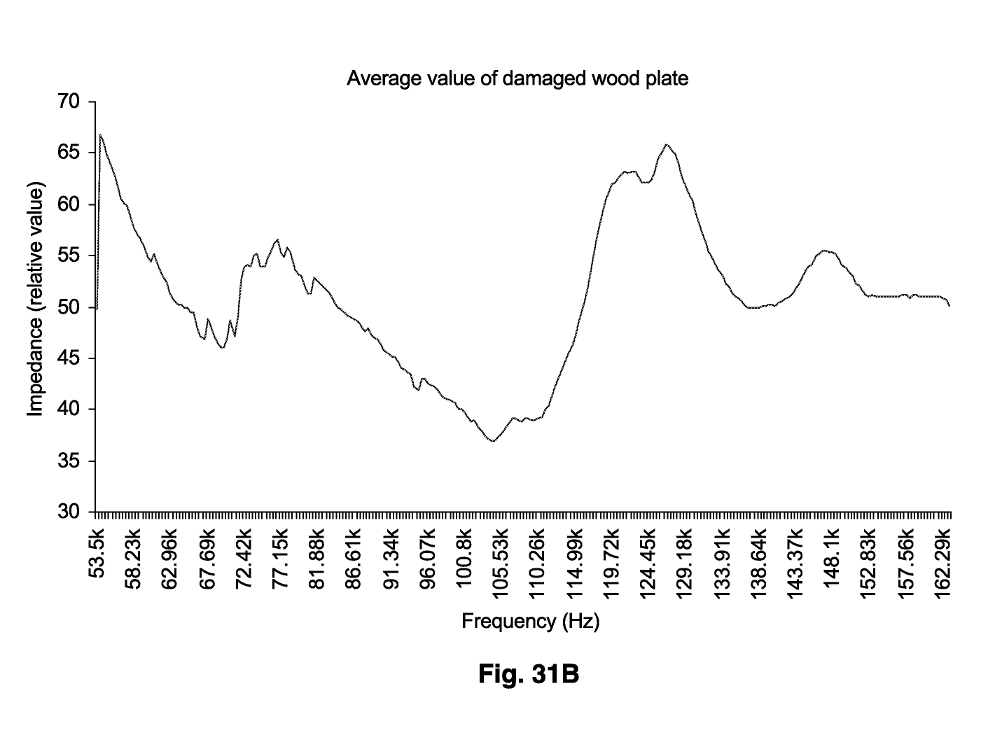

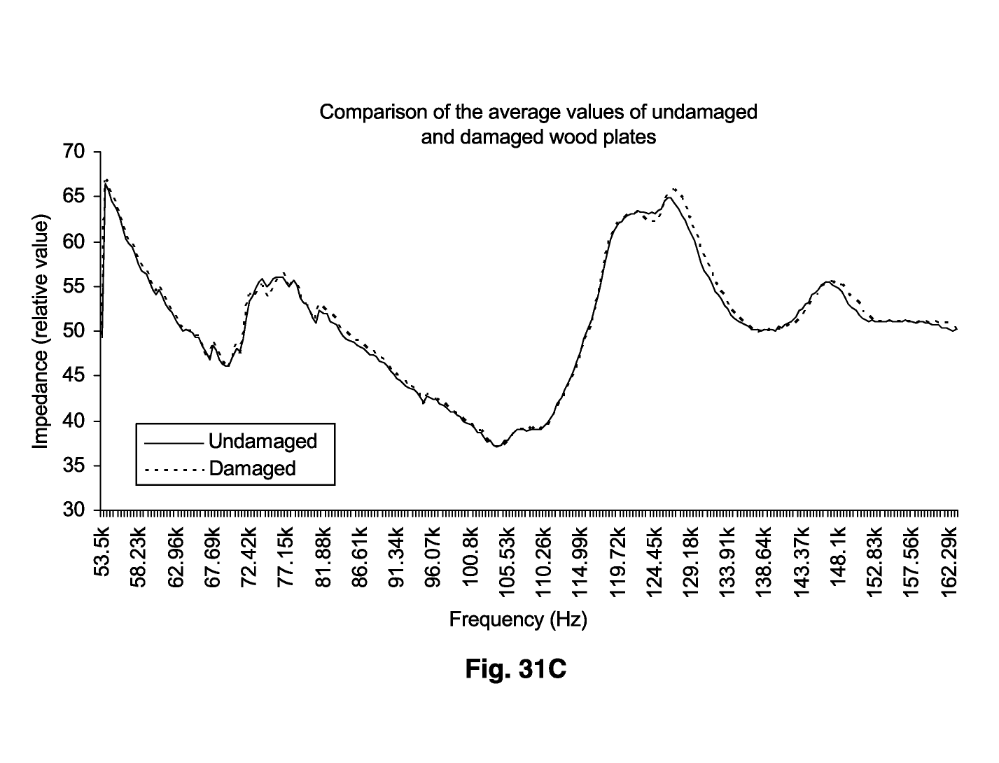

Refer now to FIGS. 30A and 30B, which show plots of the undamaged and damaged wood plate impedance-frequency curves, respectively. In each of these plots, there are also 30 series of data acquired to generate each of the curves respectively. The average values of the undamaged and damaged wood plate's impedance-frequency curves are shown in FIGS. 31A and 31B, respectively, following with a comparison of the curves in FIG. 31C.

Refer now to FIG. 31C, where it appears that there are some differences between the undamaged and damaged wood in the range from about 120 kHz to 130 kHz. These shifts appear to be the largest changes between the undamaged and damaged wood.

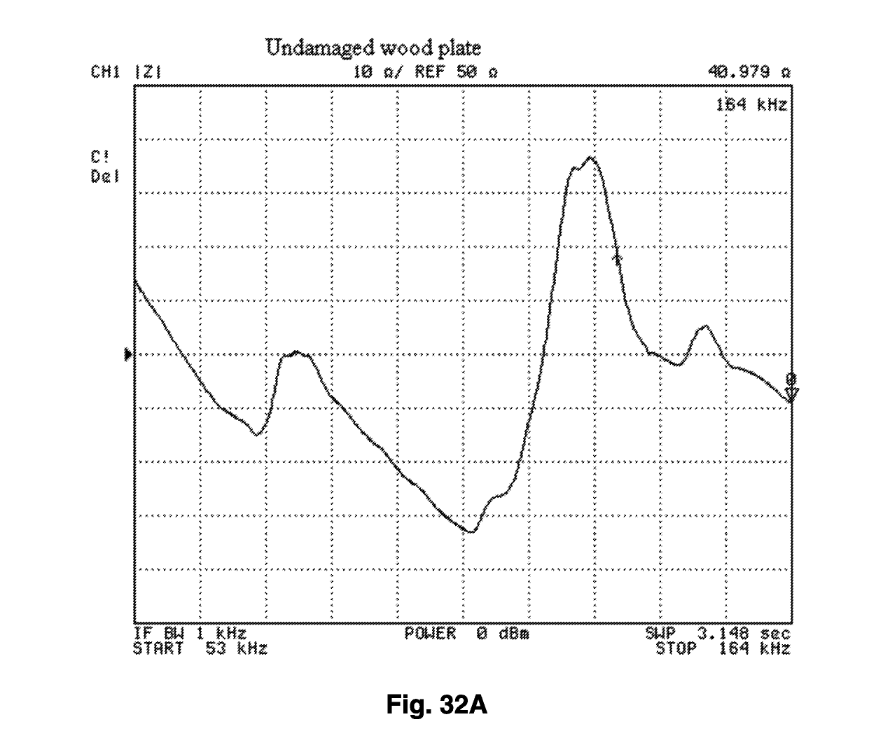

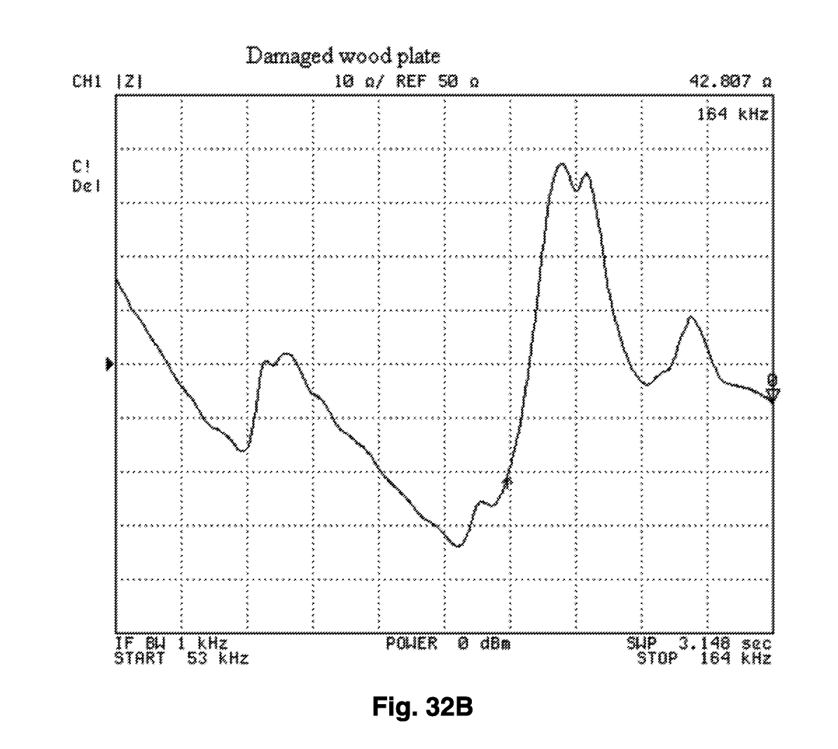

Refer now to FIGS. 32A and 32B, which are respectively undamaged and damaged wood plates impedance-frequency curves plotted by Agilent 4395A impedance analyzer. Here, the Agilent analyzer shows test results mimic the test circuit produced by the test circuit in FIGS. 31A and 31B.

The characteristics of the electrical impedance models of the aluminum plate and the wood plate are not the same. The aluminum plate has definitive resonant frequencies which plot versus impedance as clear resonant peaks; however, the wood plate has clear peaks and valleys. Therefore, it is easier to identify the curve shape changes. This is analogous to “thumping” wood and aluminum, which produce different acoustic results that are typically recognizable.

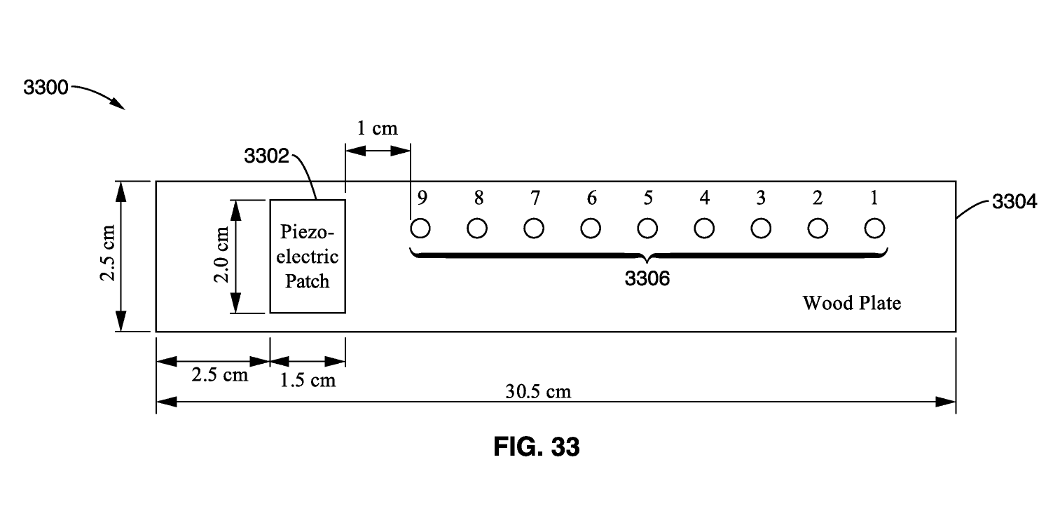

Refer now to FIG. 33, where the piezoelectric sensing range in a wood plate is determined 3300. The experimental setup is shown in FIG. 33. A piezoelectric patch 3302 (1.5×2.0×0.02 cm³) was attached to a wood plate 3304 (2.5×30.5×0.5 cm³). The impedance of the undamaged plate was measured. Then nine 3 mm diameter holes 3306 were drilled continuously from the right side of the wood plate towards one edge of the piezoelectric patch. The distance between two holes was 2.5 cm. After each hole was drilled, the electrical impedance of the piezoelectric patch was measured.

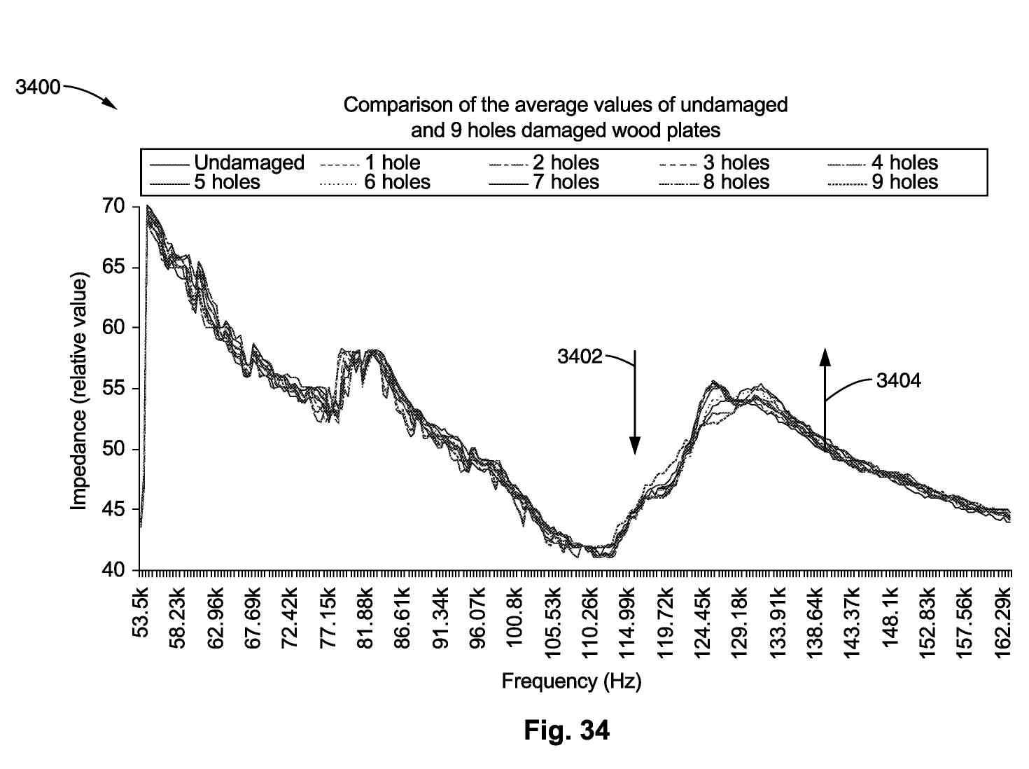

Refer now to FIG. 34, which shows the impedance-frequency curves 3400 of the undamaged and 9 holes damaged wood plates. Each curve in this plot is the average value of a set of 30 series of acquired data. It can be seen from these curves that the main differences appear in the frequency range from 115 kHz to 140 kHz. There appears to be no significant difference in the curves until the sixth hole was drilled. From the sixth hole in the series on, the amplitude of the impedance at the frequency 126 kHz begins to decrease 3402 and the amplitude of the impedance at the frequency 132 kHz begins to increase 3406. Therefore, it can be concluded that the sensing range of one piezoelectric patch in the wood plate in this experiment appears to be about 8.5 cm in distance.

Although these experiments do not take the environmental effects into account and does not compare the impedance value quantitatively, the variations in quality is enough to demonstrate that the impedance-based structural health monitoring circuit described here can be used to detect electrical impedance and impedance variations, which may be indicative of the physical changes in the host structure under test.

Advantages of Impedance-Based Structural Health Monitoring Circuit

Traditional methods of impedance monitoring either use an impedance analyzer, or a FFT analyzer. The proposed impedance-based structural health monitoring circuit described herein does not need these analyzers. Based on the idea of the bridge circuit, the invented circuit can generate a frequency sweep, measure, and record electrical impedance modulus relative value of piezoelectric patch. However, compared to traditional methods, the cost is much less. According to measurements, the total power consumption of the invention is about 2.0 Watts.

Impedance monitoring is implemented by electronic circuits, which contributes to the integration with self-power circuit and wireless communication circuit. Therefore, a smart and intelligent system on a chip may be realized through Very Large Scale Integration (VLSI) design in the future. Also, power and space will be reduced.

### Conclusions

Piezoelectric materials as one of the intelligent materials are helpful for monitoring structural integrity, improving reliability, and reducing maintenance costs of systems and structures. The principle of the piezoelectric impedance-based structural health monitoring technique is to measure the impedance of a piezoelectric patch in a certain frequency range. Electrical impedance variations indicate physical changes in the structure due to coupling between electrical impedance and mechanical impedance. However, traditional methods usually introduce impedance analyzers or FFT analyzers, which increase the costs of investigation. If impedance monitoring can be implemented through an electronic circuit, not only will costs be lowered, but also the integration of an impedance monitoring circuit, a self-power circuit, and a wireless communication circuit will be realized. In addition, the size of the actual measurement device can be reduced dramatically for wide application. A smart and intelligent system on a chip through a VLSI design can be realized in the future. The experiments demonstrated that structural health monitoring can be realized using an electronic circuit, and the proposed impedance-based structural health monitoring circuit can measure the electrical impedance on different types and conditions of structures (both aluminum structures and wood structures) in a frequency range of 53 kHz −164 kHz.

Although the description above contains many details, these should not be construed as limiting the scope of the invention but as merely providing illustrations of some of the presently preferred embodiments of this invention. Therefore, it will be appreciated that the scope of the present invention fully encompasses other embodiments which may become obvious to those skilled in the art, and that the scope of the present invention is accordingly to be limited by nothing other than the appended claims, in which reference to an element in the singular is not intended to mean “one and only one” unless explicitly so stated, but rather “one or more.” All structural, chemical, and functional equivalents to the elements of the above-described preferred embodiment that are known to those of ordinary skill in the art are expressly incorporated herein by reference and are intended to be encompassed by the present claims. Moreover, it is not necessary for a device or method to address each and every problem sought to be solved by the present invention, for it to be encompassed by the present claims. Furthermore, no element, component, or method step in the present disclosure is intended to be dedicated to the public regardless of whether the element, component, or method step is explicitly recited in the claims. No claim element herein is to be construed under the provisions of 35 U.S.C. 112, sixth paragraph, unless the element is expressly recited using the phrase “means for.”

TABLE 1
Function Table

| C̅S̅ | I̅N̅C̅ | U/ D̅ | Mode |
|---|---|---|---|
| L | ↓ | H | Wiper Up |
| L | ↓ | L | Wiper Down |
| H | X | X | Inactive |

L = Voltage Level Low;
H = Voltage Level High;
X = Either L or H;
↓ = Falling Edge of the Clock.

TABLE 2
Logic Table

| Vi | The output of U1 | The output of U2 | Vo |
|---|---|---|---|
| Vi > 150 mV | 1 | 0 | 0 |
| Vi < −150 mV | 0 | 1 | 0 |
| −150 mV < Vi < 150 mV | 0 | 0 | 1 |

What is claimed is:

1. An apparatus, comprising:
a piezoelectric patch attached to a structure;
means for measuring electrical impedance of the piezoelectric patch; and
means for outputting the measured the electrical impedance of said piezoelectric patch at an input frequency to a computer readable medium.

2. The apparatus of claim 1, wherein the means for measuring comprises:
a resonant bridge, comprising:
a variable reactance as an element in a first leg in the resonant bridge, and
the piezoelectric patch as an element in a second leg in the resonant bridge;
a clock generator that drives a frequency input to the resonant bridge;
a first peak detector electrically connected to the first leg of the resonant bridge;
a second peak detector electrically connected to the second leg of the resonant bridge;
a differential amplifier comprising inputs from the two peak detector outputs;
a window comparator having an input coupled to an output of the differential amplifier; and
a control circuit having an input coupled to an output of the window comparator;
wherein an output of the control circuit independently controls the variable reactance and the clock generator.

3. The apparatus of claim 2, wherein the variable reactance comprises one or more elements selected from a group consisting of: a digitally controlled resistor, a digitally controlled capacitor, and a digitally controlled inductor.

4. The apparatus of claim 2, comprising:
means for monitoring a state of health the structure.

5. The apparatus of claim 4, wherein the means for monitoring comprises:
a comparison between an initial known good state of the structure; and
a subsequent unknown state of the structure.

6. The apparatus of claim 5, wherein the known good state and the subsequent unknown state are determined by a sweep of frequencies and their corresponding variable reactance set points to achieve balance of the resonant bridge.

7. An apparatus, comprising:
a piezoelectric patch attached to a structure;
a clock generator;
a bridge circuit comprising an input coupled to an output of said clock generator, said bridge circuit configured to monitor variations in electrical impedance of said piezoelectric patch;
a set of two peak detectors, each with an input coupled to an output of said bridge circuit;
a differential amplifier with inputs coupled to an output of the two peak detectors;
a comparator with an input coupled to an output of the differential amplifier;
a control circuit with an input coupled to an output of said comparator, wherein:
the control circuit controls an output frequency of the clock generator, and
the control circuit controls a variable reactance within the bridge circuit; and
a data output to a computer readable medium, comprising a set point of the clock generator and a set point of the variable reactance within the bridge circuit.

8. An apparatus as recited in claim 7, wherein the variable reactance comprises a digital controlled component, such as a digital resistor or digital capacitor.

9. A structural heath monitoring apparatus, comprising:
a clock generator;
a bridge circuit having an input coupled to an output of said clock generator, said bridge circuit configured for monitoring variations in electrical impedance of said piezoelectric patch;
a set of two peak detectors, each with an input coupled to an output of said bridge circuit;
a differential amplifier with inputs coupled to an output of the two peak detectors;
a comparator with an input coupled to an output of the differential amplifier;
a control circuit with an input coupled to an output of said comparator, wherein:
the control circuit controls an output frequency of the clock generator, and
the control circuit controls a variable reactance within the bridge circuit;
wherein said apparatus is configured to electrically couple the piezoelectric patch to a structure and to monitor variations in electrical impedance in the piezoelectric patch that are indicative of structural heath of said structure; and
a data output to a computer readable medium, comprising a set point of the clock generator and a set point of the variable reactance within the bridge circuit.

10. An apparatus as recited in claim 9, wherein the bridge circuit variable reactance comprises a digital resistor or a digital capacitor.

11. A method of structural health monitoring, comprising:
providing a structural health monitoring circuit attached to a structure;
providing an initial known good frequency sweep of the structural health monitoring circuit attached to the structure;
subsequently sweeping the structural health monitoring circuit attached to the structure to generate a contemporaneous frequency sweep; and
comparing the initial known good frequency sweep with the contemporaneous frequency sweep to generate a differential error.

12. The method of claim 11, comprising:
outputting to a computer readable medium the differential error.

13. The method of claim 12, wherein the comparing step is a digital comparing step.

14. The method of claim 12, wherein the comparing step is an analog comparing step.

15. The method of claim 12, wherein the initial known good frequency sweep comprises one or more frequencies.

16. The method of claim 15, wherein the initial known good frequency sweep is performed in-situ after the structure has been completed.

17. The method of claim 15, wherein the initial known good frequency sweep is performed prior to installation of the structure.

18. The method of claim 15, wherein the initial known good frequency sweep is generated off-line through numerical modeling of the structure.

19. The method of claim 15, wherein the initial known good frequency sweep spans a frequency range from about 53 kHz to about 164 kHz.

20. The method of claim 11, comprising:
generating an alarm when the differential error exceeds an error limit.

21. The method of claim 20, comprising:
transmitting the alarm a computer readable medium.

22. The method of claim 20, wherein the alarm is an audible and/or visual alarm for personnel that may be injured by damage to the structure.

23. The method of claim 20, wherein the error limit is based on an average calculation.

24. The method of claim 20, wherein the error limit is based on a root mean square (RMS) calculation.

25. A computer readable medium comprising a programming executable capable of performing on a computer the method of claim 11.
